(19) United States
(12) Patent Application Publication
(10) Pub. No.: US 2026/0181835 A1
(43) Pub. Date: Jun. 25, 2026

(54) COOLING SYSTEMS FOR COMPUTING HARDWARE

(71) Applicant: MELLANOX TECHNOLOGIES, LTD., Yokneam (IL)

(72) Inventors: Carl Thomas Gray, Apex, NC (US); Tahir Cader, Spokane Valley, WA (US); John Michael Wilson, Wake Forest, NC (US); Walker Joseph Turner, Jacksonville Beach, FL (US); John Franz, Tomball, TX (US); Elad Mentovich, Tel Aviv (IL)

(21) Appl. No.: 19/068,424

(22) Filed: Mar. 3, 2025

Related U.S. Application Data
(60) Provisional application No. 63/736,542, filed on Dec. 19, 2024.

(51) Int. Cl. H05K 7/20; H01L 25/16; H10B 80/00; H10D 80/30

(52) U.S. Cl. CPC H05K 7/20772; H10B 80/00; H10D 80/30; H10W 90/00

(57) ABSTRACT

Systems are disclosed that support improved cooling of processing units and other computing components in a datacenter or elsewhere. An example of such a system may include a processing and/or memory layer comprising at least one of a processing unit and a memory die, and a cooling substrate that cools a bottom side of the processing and/or memory layer.

### CROSS-REFERENCE TO RELATED APPLICATION

The present application claims the benefit of and priority, under 35 U.S.C. § 119, to U.S. Provisional Application Ser. No. 63/736,542, filed Dec. 19, 2024, entitled “BOTTOM-SIDE COOLING,” the entire disclosure of which is hereby incorporated herein by reference, in its entirety, for all that it teaches and for all purposes.

### FIELD OF THE DISCLOSURE

Embodiments of the present disclosure relate generally to thermal solutions for computing hardware, and more specifically to cooling components of a datacenter.

### BACKGROUND

Datacenter switch systems and associated modules may include connections between other switch systems, servers, racks, and devices. Such connections may be made using cables, transceivers, cage receptacles, and connector assemblies, which may include a shell or housing configured to protect these connections from damage.

As datacenters continue to operate at higher speeds (e.g., 100 Gb and beyond), the thermal demands on the components in the datacenters increase as well. Heat generation in datacenters occurs primarily due to the electricity used by servers, storage devices, and other hardware components, where nearly all the consumed energy is converted into heat as a byproduct of processing data, essentially meaning that for every watt of electricity used, a watt of heat is produced. The heat requires active and continuous management; otherwise, components of the datacenter may fail under extreme thermal loads. For instance, both cage receptacles and processing units can generate heat during operation, which can result in the failure of those cage receptacles and processing units as well as the failure of system components connected thereto.

### GENERAL DESCRIPTION

Embodiments of the present disclosure aim to address at least some issues associated with thermal loads in a datacenter, and more specifically with thermal loads generated by graphics processing units, central processing units, co-packaged optics, and other datacenter components. Specifically, and without limitation, embodiments of the present disclosure provide systems for bottom-side cooling of Graphics Processing Units (GPUs), Central Processing Units (CPUs), and other chips to deal with hotspot management and cooling of a vertical power delivery (VPD) infrastructure. This dual cooling approach enables higher performance and power consumption without overheating.

As power consumption increases, spreading out in the XY dimension is not feasible due to space constraints. This necessitates vertical stacking, which introduces challenges such as routing power and signals through a dense GPU, and difficulties with cooling due to heat generated in one or more components lower in the stack having to flow through one or more components higher in the stack—including components such as high-bandwidth memory that may have a very high thermal resistance. When components are stacked vertically, thermal resistance increases, making it harder to dissipate heat. This requires maintaining a temperature gradient to force heat through the stack, which can limit power and performance if not managed properly.

A cooling substrate as disclosed herein, comprising one or more microfluidic channels as well as power, ground, and signal TSVs, addresses these challenges by providing integrated bottom-side cooling and more effective heat management, while enabling power and signals to be passed therethrough. Use of such a cooling substrate thus addresses the challenges of vertical stacking, and substantially increases available computation power while running memory at full bandwidth.

A system according to embodiments of the present disclosure may have at least one processing unit (e.g., a GPU or a CPU), at least one memory die, and at least one cold plate. The at least one memory die and at least one processing unit may be part of a processing and/or memory layer that may be positioned between the at least one cold plate and another cooling substrate that provides bottom-side cooling of the processing and/or memory layer.

In some examples, the processing and/or memory layer may be provided in a 2.5D package or a 3D package (e.g. dense 3D package having stacking memory on top of the GPU and the interposer) providing flexibility in design. 2.5D packaging having memory next to the GPU on the same plane, with the memory being 3D stacked itself is advantageous for combining various components and reducing footprints. It suits applications in high-performance computing and AI accelerators. 3D packaging provides additional integration and reduced interconnect lengths, among other things. 3D packaging of GPUs saves board space and allows placement of components like voltage regulators (VRs), co-packaged optics (CPO), and other supporting infrastructure around the GPUs. 2.5D packaging, also known as 2.5D interposer technology, is an intermediate step between traditional 2D packaging and 3D packaging. In 2.5D packaging, multiple semiconductor dies, typically from different process technologies, are placed side-by-side on a silicon interposer. 3D packaging takes integration to the next level by stacking multiple semiconductor dies on top of each other, creating a three-dimensional structure.

In at least one embodiment, an artificial intelligence (AI) data center infrastructure platform is provided. Examples of an AI data center infrastructure platform are Nvidia® DGX™ SuperPOD™ and DGX™ Foundry. In at least one embodiment, an AI data center infrastructure platform provides accelerated infrastructure and/or scalable performance tailored for AI such as machine learning (ML) and other high-performance computing (HPC) loads. In at least one embodiment, AI system may include a purpose-built computing system (e.g., a super-computer or an HPC) configured for inferencing, deep learning, machine learning, and/or other artificial intelligence tasks. In at least one embodiment, AI system (e.g., NVIDIA's DGX) may include GPU-optimized software (e.g., a software stack) that may be executed using a plurality of GPUs, in addition to CPUs, RAM, storage, and/or other components, features, or functionality. In at least one embodiment, one or more AI systems may be implemented in cloud (e.g., in a data center) for performing some or all of AI-based processing tasks of system.

Insulation materials like silicon dioxide may be used to prevent short circuits when water flows through the TSVs. This is crucial to ensure the reliability and safety of the cooling system.

The at least one processing unit may be provided on a silicon interposer. The silicon interposer may further have the cooling substrate positioned adjacent thereto. The cooling substrate may include one or more microfluidic channels therein that carry a fluid therein to facilitate heat transfer away from the at least one processing unit and/or silicon interposer. The cooling substrate may supplement cooling provided by the at least one cold plate or vice versa. The cooling substrate may also comprise one or more Through Silicon Vias (TSVs) to allow the transfer of electrical signals through the cooling substrate. The placement of power, ground, and signal TSVs in the cooling substrate are located at different densities and positions to optimize performance and cooling.

The present disclosure relates in general to cooling data center components. Datacenters comprise multiple components, including processing units and other chips interconnected using optical, active, and high-powered cables and associated connector assemblies used in conjunction with datacenter switch systems, modules, and other optical and electrical components. In particular, cages, shells, and housings of connector and receptacle assemblies may utilize heat dissipation units and elements that are configured to increase the thermal performance of connector assemblies.

Datacenter switch systems and associated modules may generally include connections between other switch systems, servers, racks, and devices. Such connections may be made using cables, transceivers, cage receptacles, and connector assemblies, which may include a shell or housing configured to protect these connections from damage. Often, these cage receptacles can generate heat during operation, which can result in the failure of system components.

Example aspects of the present disclosure include solutions to help cool one or more components of a datacenter as described herein.

In some embodiments a system is provided that includes: a processing and/or memory layer comprising at least one of a processing unit and a memory die; and a cooling substrate that cools a bottom side of the processing and/or memory layer.

According to some aspects, the system further includes a semiconductor interposer. In some examples, the processing unit is positioned between the memory die and the semiconductor interposer. In some examples, the semiconductor interposer comprises co-packaged optics mounted thereon.

According to some aspects, the system further includes a cold plate that cools a top side of the processing and/or memory layer. In some examples, the processing unit is positioned between the memory die and the cold plate.

According to some aspects, the cooling substrate comprises one or more microfluidic channels therein that carry a fluid to facilitate heat transfer away from the processing and/or memory layer.

According to some aspects, the cooling substrate comprises a thermally-conductive material suitable to conduct heat away from the processing and/or memory layer.

According to some aspects, the processing unit comprises a Graphics Processing Unit (GPU).

According to some aspects, the memory die comprises a high-bandwidth memory (HBM) stack and/or a dynamic random access memory (DRAM) layer.

According to some aspects, the processing and/or memory layer comprises both the processing unit and the memory die. In some examples, the processing unit is positioned between the memory die and the cooling substrate. In some examples, the memory die is positioned between the processing unit and the cooling substrate. In some examples, the processing and/or memory layer comprises a 2.5D package. In some examples, the processing and/or memory layer comprises a 3D package.

According to some aspects, the cooling substrate comprises one or more conductive vias. In some examples, the cooling substrate comprises one or more microfluidic channels therein that carry a fluid to facilitate heat transfer away from the processing and/or memory layer, wherein the one or more conductive vias are electrically isolated from the one or more microfluidic channels.

In some embodiments a bottom-cooled processing stack is provided that includes: a cooling substrate comprising one or more microfluidic channels therein; and at least one processing unit positioned relative to the cooling substrate such that a bottom side of the at least one processing unit is cooled by a fluid flowing through the one or more microfluidic channels.

According to some aspects, the system further includes at least one memory die. In some examples, the at least one memory die is positioned between the at least one processing unit and the cooling substrate. In some examples, the at least one processing unit is positioned between the at least one memory die and the cooling substrate.

According to some aspects, the system further includes a semiconductor interposer.

According to some aspects, the system further includes a cold plate that cools a top side of the at least one processing unit and the at least one memory die. In some examples, the at least one processing unit and the at least one memory die are provided in a 2.5D or 3D package that is sandwiched between the cold plate and the cooling substrate.

According to some aspects, the cooling substrate includes one or more microfluidic channels and one or more conductive vias that are electrically isolated from the one or more microfluidic channels.

In some embodiments, a bottom-cooled processing stack is provided that includes: a cooling substrate comprising one or more heat transfer channels therein; and at least one processing unit positioned relative to the cooling substrate such that a bottom side of the at least one processing unit is cooled by the one or more heat transfer channels of the cooling substrate.

Any aspect in combination with any one or more other aspects.

Any one or more of the features disclosed herein.

Any one or more of the features as substantially disclosed herein.

Any one or more of the features as substantially disclosed herein in combination with any one or more other features as substantially disclosed herein.

Any one of the aspects/features/implementations in combination with any one or more other aspects/features/implementations.

Use of any one or more of the aspects or features as disclosed herein.

It is to be appreciated that any feature described herein can be claimed in combination with any other feature(s) as described herein, regardless of whether the features come from the same described implementation.

The details of one or more aspects of the disclosure are set forth in the accompanying drawings and the description below. Other features, objects, and advantages of the techniques described in this disclosure will be apparent from the description and drawings, and from the claims.

Numerous additional features and advantages of the present disclosure will become apparent to those skilled in the art upon consideration of the implementation descriptions provided hereinbelow.

Additional features and advantages are described herein and will be apparent from the following Description and the figures.

### BRIEF DESCRIPTION OF THE SEVERAL VIEWS OF THE DRAWINGS

Having thus described the disclosure in general terms, reference will now be made to the accompanying drawings, which are not necessarily drawn to scale:

FIG. 1 is a block diagram illustrating an example network architecture according to at least some embodiments of the present disclosure;

FIG. 2 schematically illustrates various components of a network architecture according to at least some embodiments of the present disclosure;

FIG. 3 is a perspective view of a datacenter rack according to at least some embodiments of the present disclosure;

FIG. 4 is a block diagram of a 3D stack with bottom-side cooling according to embodiments of the present disclosure;

FIG. 5 is a block diagram of a 2.5D stack with bottom-side cooling according to embodiments of the present disclosure;

FIG. 6 is a perspective view of a cage receptacle assembly according to at least some embodiments of the present disclosure;

FIGS. 7A-7B illustrate an example cable connector according to at least some embodiments of the present disclosure;

FIG. 8 is an exploded view of a 3D stack with bottom-side cooling according to embodiments of the present disclosure;

FIG. 9A is a side cross-sectional view of a cooling substrate according to embodiments of the present disclosure;

FIG. 9B is a top plan view of a cooling substrate according to embodiments of the present disclosure;

FIG. 9C is a side cross-sectional view of a cooling substrate according to embodiments of the present disclosure;

FIG. 10A depicts several stack configurations used in a study of embodiments of the present disclosure;

FIG. 10B depicts the results of the study of embodiments of the present disclosure;

FIG. 11 is a block diagram of a system according to embodiments of the present disclosure;

FIG. 12 is a block diagram illustrating a computer system according to at least some embodiments of the present disclosure;

FIG. 13 is a block diagram illustrating details of network devices according to at least some embodiments of the present disclosure; and

FIG. 14 is a block diagram illustrating further details of a datacenter and components thereof according to at least some embodiments of the present disclosure.

Like reference numbers and designations in the various drawings may indicate like elements.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It is understood that various changes may be made in the function and arrangement of elements without departing from the spirit and scope of the appended claims.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

Various aspects of the present disclosure will be described herein with reference to drawings that are schematic illustrations of idealized configurations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

The present disclosure now will be described more fully hereinafter with reference to the accompanying figures in which some but not all embodiments of the disclosures are shown. Indeed, the present disclosure may be embodied in many different forms and should not be construed as limited to the embodiments set forth herein.

Like numbers refer to like elements throughout. As used herein, terms such as “front,” “rear,” “top,” etc. are used in the examples provided below to describe the position of certain components or portions of components in an installed and operational configuration. As used herein, the term “module” encompasses hardware, software and/or firmware configured to perform one or more particular functions, including but not limited to conversion between electrical and optical signals and transmission of the same. As would be evident to one of ordinary skill in the art in light of the present disclosure, the term “substantially” indicates that the referenced element or associated description is accurate to within applicable engineering tolerances.

Processing stacks according to embodiments of the present disclosure may be connected to one another and to other datacenter components using a pluggable connector such as an octal small form factor pluggable (OSFP); a Quad Small Form-factor Pluggable (QSFP) connector; or any other connector (e.g., Small Form Pluggable (SFP), C-Form-factor Pluggable (CFP), and the like). Moreover, such connections may use any cable (e.g., passive copper cable (PCC), active copper cable (ACC), or the like) or interconnect utilized by datacenter racks and associated switch modules (e.g., an active optical module (AOM), QSFP transceiver module, or the like). Pluggable network interface devices, or pluggable network interface modules, generally include a PCB, or circuit substrate, that is at least partially embedded in a housing. Each pluggable network interface device includes at least one heat-generating circuit package such as a clock and data recovery circuit (“CDR”), microcontroller, driver, chips, and/or other circuitry attached to the PCB that generates heat during use, or while in operation. As can be appreciated, the efficient dissipation of heat is critical to ensuring proper operation. For instance, in certain pluggable network interface devices, like Extended Detection and Response (“XDR”) transceivers, the device's total power can reach about 35 Watts, and the CDR component alone can reach up to 25 Watts. Consuming this amount of power, especially in small form factor pluggable devices, naturally generates high temperatures and thermal energy (e.g., temperatures at or around 121° C., etc.).

Additionally, processing stacks according to embodiments of the present disclosure may utilize transceiver systems to facilitate communication with other datacenter components, which transceiver systems may comprise, for example, a vertical-cavity surface-emitting laser (VCSEL) as one element thereof. However, embodiments of the present disclosure may be equally applicable for use with any transceiver system and/or element. Similarly, communications between processing stacks according to embodiments of the present disclosure may be facilitated by a switch module configured to receive a cage receptacle assembly to allow signals to pass between a cable connector and the switch module. The present disclosure, however, contemplates that a network interface, a high-capacity adapter, or any other applicable networking interface may equally be used instead or in conjunction with the switch module to receive the cage receptacle and facilitate communications among various datacenter components.

Embodiments of the present disclosure are contemplated to be deployed in a datacenter environment. While embodiments will be described in connection with certain examples of datacenter environments, it should be appreciated that embodiments of the present disclosure are not so limited. Indeed, embodiments of the present disclosure contemplate the ability to deploy bottom-side cooling as disclosed herein in any number of environments including a datacenter environment or any other suitable environment that requires the management of thermal loads generated by computing components.

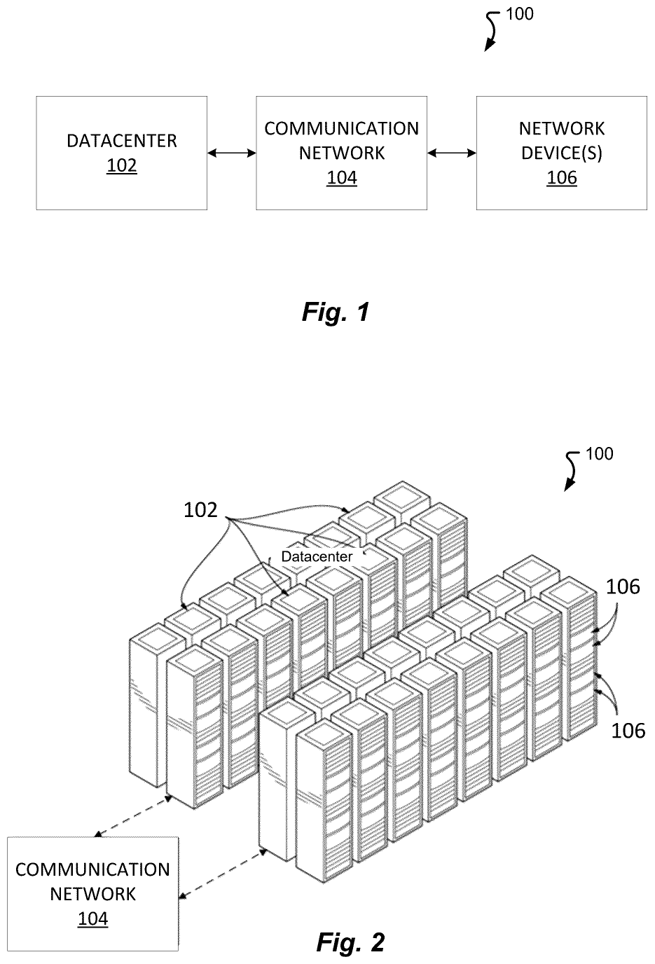

Illustrative datacenter environments and components are shown and will now be described with reference to FIGS. 1 through 14.

Datacenters, high performance computing clusters, and/or the like are often formed of various computing components or networked devices, and communication networks formed of electrical and/or optical devices may be used to enable communication between the networked devices forming these implementations. As shown in FIGS. 1, 2, and 13, for example, a network architecture 100 may include a datacenter 102, a communication network 104, and network device(s) 106. The network architecture 100 may illustrate a general computing architecture within which more specific systems and/or subsystems may function. Although described hereinafter with reference to a network architecture 100 and/or datacenter 102 within which the embodiments of the present disclosure may be implemented, the present disclosure contemplates that the transceiver resiliency devices and techniques described herein may be applicable to any communication implementation without limitation.

For example, the datacenter 102 may be a centralized facility designed to house computing resources and related components. The datacenter 102 may operate to support the infrastructure required for advanced computational tasks, for efficient, secure, and reliable operations. The datacenter 102 may include the building and structural components, including power supplies, cooling systems, fire suppression systems, and physical security measures that are configured to maintain optimal operating conditions and/or protect the equipment from environmental hazards and unauthorized access. An example datacenter 102 may include high-performance servers or compute nodes, often arranged in racks, such as those illustrated in FIG. 2, and connected through high-speed networks as described herein. These servers may include processors (e.g., central processing units (CPUs), graphics processing units (GPUs), data processing units (DPUs) and/or the like), memory (e.g., RAM), and storage solutions (e.g., hard disk drives (HDDs), solid state drives (SSDs), and/or the like. The hardware configuration may be designed for parallel processing and high throughput, catering to the demands of high-performance computing (HPC) applications.

In one example, the processors may include central processing units (CPUs), graphics processing units (GPUs), data processing units (DPUs), quantum processing units (QPUs), a plurality of parallel processing units (PPUs), and application-specific integrated circuits (ASICs). QPUs configured to perform one or more operations associated with a quantum algorithm In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU with which the local qubits are associated.

The datacenter 102 may include high-speed network equipment, such as network switches, routers, firewalls, and/or the like to facilitate fast and secure data transmission within the datacenter 102 (e.g., between the servers or compute nodes) and between external networks. The datacenter 102 may facilitate communication between servers or compute nodes through a network topology that ensures efficient data exchange, minimizes latency, and maximizes bandwidth. The network topology may dictate how various network devices, such as switches and routers, are interconnected for data flow. By implementing an effective network topology, the datacenter 102 may support high-performance computing tasks. Examples of various network topologies may include hierarchical networking topologies such as the fat tree topology, Slim Fly topology, Dragonfly topology, and/or the like. The datacenter 102 may adhere to a networking topology (e.g., a hierarchal networking topology), such as a fat tree topology, a Slim Fly topology, a Dragonfly topology, and/or the like. The datacenter 102 routes traffic amongst the network switches and servers therein, and at least one layer of the topology in the datacenter 102 is coupled to the communication network 104 to allow networking traffic to flow between the datacenter 102 and the network device(s) 106.

The communication network 104 may communicably couple the datacenter 102 with network device(s) 106 and other external devices for data exchange and connectivity. Examples of the communication network 104 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. The ability of the communication network 104 to incorporate multiple network types and configurations may allow the datacenter 102 to adapt to diverse application needs, from general data communication to specialized HPC tasks. As described herein, the communication network 104 may leverage various optical components to establish communication links (e.g., communicably couple) between components in the architecture 100. As such, the communication network 104 may include various optical devices, transceivers, modules, and/or the like that are configured to generate optical signals (e.g., provide optical transmitter functionality) and/or receive optical signals (e.g., provide optical receiver functionality).

The network device(s) 106 may include a variety of computing devices capable of transmitting and receiving signals over the communication network 104. The network device(s) 106 may range from personal computing devices to complex server configurations. Examples include Personal Computers (PCs), laptops, tablets, smartphones, and servers. The network device(s) 106 may facilitate user interactions with the datacenter 102, allowing for data input, retrieval, and processing from remote locations. In addition to individual computing devices, the network device(s) 106 may also include collections of servers or additional datacenters. For instance, these could be other datacenters similar to or the same as datacenter 102. Such an interconnection may allow for the formation of a distributed computing environment for improved redundancy, load balancing, and disaster recovery capabilities. By linking multiple datacenters, the network architecture 100 may leverage geographically dispersed resources, optimizing performance and ensuring high availability.

As described herein, the datacenter 102 and/or the network device(s) 106 may include storage devices and processing circuitry for executing computing tasks, such as controlling the flow of data internally and over the communication network 104. The processing circuitry may include software, hardware, or a combination thereof. For example, the processing circuitry may include a memory containing executable instructions and a processor (e.g., a microprocessor) that executes these instructions. The memory may correspond to any suitable type of memory device or collection of memory devices configured to store instructions. Non-limiting examples of suitable memory devices include Flash memory, Random Access Memory (RAM), Read Only Memory (ROM), variants thereof, combinations thereof, or similar technologies. In specific embodiments, the memory and processor may be integrated into a common device, such as a microprocessor with integrated memory. Additionally, or alternatively, the processing circuitry may comprise hardware components, such as an application-specific integrated circuit (ASIC). Other non-limiting examples of processing circuitry include Integrated Circuit (IC) chips, CPUs, GPUs, microprocessors, Field Programmable Gate Arrays (FPGAs), collections of logic gates or transistors, resistors, capacitors, inductors, and diodes. Some or all of the processing circuitry may be provided on a Printed Circuit Board (PCB) or a collection of PCBs. It should be appreciated that any appropriate type of electrical component or collection of electrical components may be suitable for inclusion in the processing circuitry.

In addition, although not explicitly shown, the present disclosure contemplates that the datacenter 102 and network device(s) 106 may include one or more communication interfaces for facilitating wired and/or wireless communication between one another and other unillustrated elements of the network architecture 100. These communication interfaces may include a variety of technologies, including but not limited to Ethernet ports, fiber optic connections, Wi-Fi® transceivers, Bluetooth® modules, and cellular communication modules for integration and interoperability among the various components within the network architecture 100.

Furthermore, the present disclosure contemplates that the network architecture 100 may include additional components and functionalities. For example, the network architecture may include, without limitation, additional processing units, specialized accelerators (such as Tensor Processing Units or TPUs), enhanced security modules, and redundant power supplies. The inclusion of these elements may be intended to ensure that the network architecture 100 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the network architecture 100.

In high-capacity datacenter networks, the communication network 104 may leverage optical transceivers that transmit and receive optical signals over optical fibers or other optical communication mediums to establish connection between devices in the architecture 100.

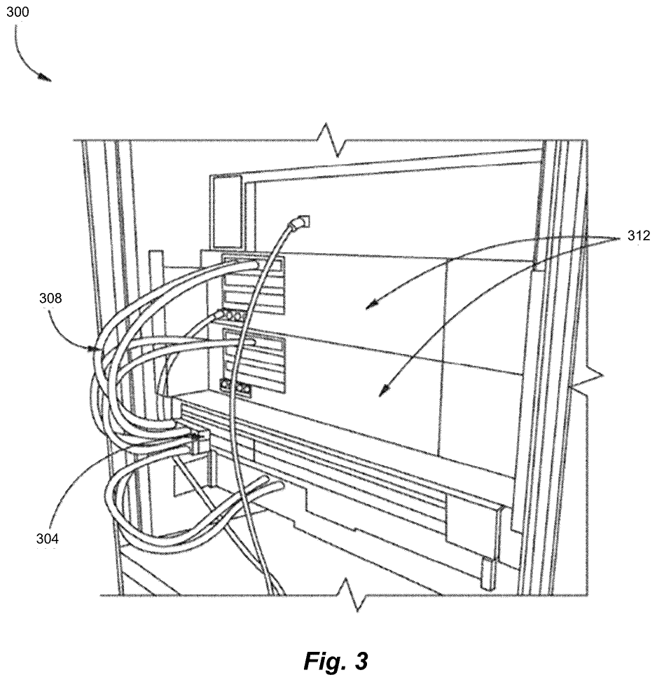

FIG. 3 illustrates an example datacenter rack 300, or cabinet that is designed to house servers, networking devices, modules, and other datacenter 102 computing equipment and used in conjunction with optical cable(s) 308.

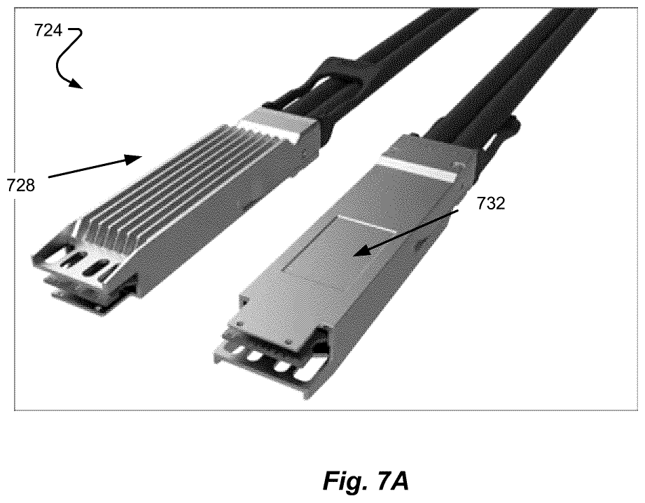

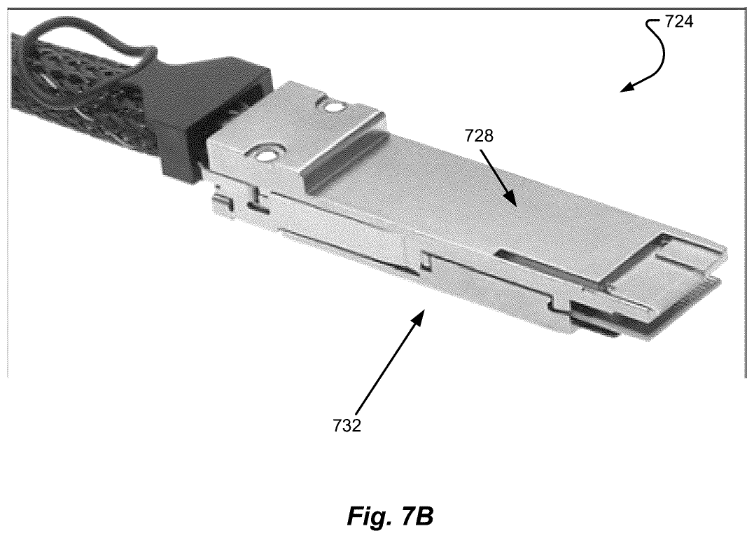

Different types of cable connectors, such as those illustrated in FIGS. 7A and/or 7B, exist for enabling transmission of signals (optical and/or electrical) between switch modules and other equipment in a datacenter. For example, OSFP connectors and cables, as well as other forms of connectors such as QSFP, Small Form Pluggable (SFP), and C-Form-factor Pluggable (CFP) connectors provide high-speed information operations interface interconnects. Regardless of the type of cable connectors, these transceivers may interface a switch system board, such as a motherboard in a switch system, to a fiber optic or copper networking cable, such as by making connections between switch modules 312 as shown in FIG. 3.

With continued reference to FIG. 3, for example, a switch module 312 (or other interconnect module), which may house an application-specific integrated circuit (ASIC) as well as other internal components (not visible), is typically incorporated into a datacenter 102 or 1400 via connections to other switch systems, servers, racks, and network components. A switch module 312 may, for example, interact with other components of the datacenter 102 or 1400 via external optical cables 308 and possible transceiver systems housed in the end of an optical cable 308. These optical cables 308 and transceivers may allow connections between a switch module 312 and the other components of the datacenter 102 or 1400 via cage receptacle assemblies 304.

The switch modules 312 may be configured to be received by a datacenter rack 300 and may be configured to allow for the conversion between optical signals and electrical signals. For example, optical cables 308 may carry optical signals as inputs to the switch module 312. The optical signals may be converted to electrical signals via an opto-electronic transceiver assembly, which may form part of the optical cable 308 in cases in which the optical cable 308 is an Active Optical Cable (AOC), such as a cable that includes an OSFP connector that is received by a port of a switch module 312. In other cases, the optical cable 308 may be passive, and the switch module 312 may include opto-electronic components that convert between optical signals and electrical signals. The electrical signals may then be processed by the switch module 312 and/or routed to other computing devices, such as servers and devices on other racks or at other datacenters via other components and cables (not shown). In addition, electrical signals received from other networking devices (e.g., from other datacenters, racks, etc.) may be processed by the switch module 312 and then converted into corresponding optical signals to be transmitted via the optical cables 308, going the opposite direction.

The transmission of data as electrical signals and the conversion between optical signals and electrical signals (e.g., via an AOC and associated transceiver system or AOM) often results in the generation of heat by the components of the datacenter rack 300. As can be appreciated, higher temperatures associated with such heat emissions can correspond to the increased likelihood of failure of electrical components and/or changes in the electrical and/or optical operating parameters of the components resulting in interference with the corresponding electrical and/or optical signals. Additionally, localization or concentration of higher temperatures in electrical components (e.g., the bottom surface of the AOC, AOM, or pluggable cable connector) can result in a further increase in the likelihood of failure of electrical components located near the area of heat concentration.

Accordingly, embodiments of the disclosure described herein provide a cage receptacle assembly that is configured to provide increased thermal efficiency by allowing the heat dissipation units to be independently adjustable relative to the cage body (e.g., “floating”), so that their spatial position and orientation state is aligned with the position and orientation of the respective top or bottom surfaces of the plugged transceiver to achieve effective heat transfer from the transceiver surfaces to the heat dissipation elements. In embodiments, the contact area between the transceiver and heat dissipation unit(s) is enlarged to allow for more surface area of the transceiver contacting the heat dissipation unit(s) to distribute heat more evenly and/or to more effectively dissipate the heat to the surrounding environment to maintain lower temperatures in the components.

It should further be noted that a cable 308 (and similarly the other active optical cables described herein) and connectors may be designed to comply with any applicable standard, for example Ethernet and InfiniBand standards, such as Ethernet variants 200GBASE-FR4, 400GBASE-FR4, and 100GBASE-LR4 to support four wavelengths. Connections between the cable 308 and the switch module 312 may be facilitated by one or more of a transceiver module and a cage receptacle assembly.

With reference now to FIG. 4, a block diagram of a system 500 will be described in accordance with at least some embodiments of the present disclosure. The system 500 comprises a bottom-cooled 3D stack. The stack comprises a PCB 504, a cooling substrate 508; a silicon or other semiconductor interposer 512, supporting co-packaged optics 514; a first processing tier or layer 516; a second processing tier or layer 520; a memory layer 524; and a cold plate 528.

The silicon or other semiconductor interposer 512 is a silicon, glass, or organic substrate that provides electrical and mechanical connections between different semiconductor chips in an advanced packaging system. It serves as a bridge between integrated circuits (ICs), improving performance, power efficiency, and integration density.

The first and second processing tiers 516 and 520 may operate at different power levels. For example, the first processing tier 516 may operate at a lower power level, while the second processing tier 520 may operate at a relatively higher power level. Adjacent layers may, for example, be bonded together using wafer bonding (e.g., copper-to-copper connections or TSVs). The first processing tier 516 and the second processing tier 520 may form a stacked GPU providing a liquid-cooled GPU with a 3D chip stack and embedded cooling. The silicon interposer 512 may be placed underneath the first processing tier 516 with co-packaged optics 514 placed on the silicon interposer 512 and adjacent to the first processing tier 516. The system 500 may be one of multiple similar systems 500 that are included in a datacenter such as the datacenter 102. Electrical communication between the system 500, other systems 500, and/or other datacenter components may be accomplished through the co-packaged optics 514, which may be connected to optical, active, and/or high-powered cables and associated connector assemblies; and/or any other electrical communication apparatus or device.

The PCB 504 may be configured to receive, for example, electrical power from an external power source for powering the system 500. The PCB 504 may also comprise one or more grounded contacts, such that other components of the system 500 are able to connect to ground by maintaining electrical communication with one of the grounded contacts on the PCB 504. In some embodiments, the PCB 504 (whether in addition to or instead of the co-packaged optics 514) provides electrical signal communication with one or more other components of a datacenter (e.g., a datacenter 102) in which the system 500 is being used. Although PCBs having certain types and form factors appear in the drawings and the discussion, it should be noted that the illustrated and described types and form factors are provided by way of example only. The same is true of all other components described herein.

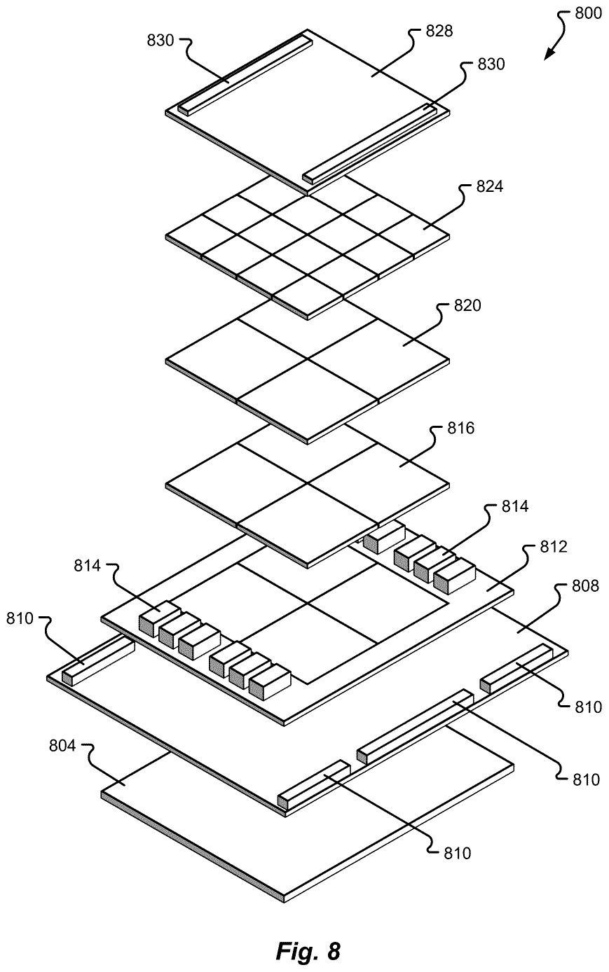

The cooling substrate 508, which is described in greater detail in connection with FIGS. 8-10, comprises a semiconductor configured with one or more thermal conductivity paths and with one or more electrical conductivity paths. The one or more thermal conductivity paths may comprise, for example, one or more channels passing through the substrate and configured to carry a heat transfer fluid forming a microfluidic substrate. The one or more thermal conductivity paths may additionally or alternatively comprise one or more solid thermal conduction elements. The thermal conductivity paths are configured to facilitate heat transfer from other elements in the system 500 (e.g., the processing layers and/or memory layers of the system 500) to the thermal conductivity media—whether heat transfer fluid, one or more solid thermal conduction elements, a combination thereof, or something else—and conduct that heat away from the system 500 (e.g., to a heat sink).

The electrical conductivity paths enable the transmission of electrical signals through the cooling substrate 508 (e.g., from the PCB 504 and/or any other layer underneath the cooling substrate 508 to or through the interposer 512 and/or any other layer above the cooling substrate 508, or vice versa). In the system 500, for example, the electrical conductivity paths enable the transmission of electrical signals from the interposer 512 to the PCB 504, and vice versa. The electrical conductivity paths in the cooling substrate 508 may also be used, for example, to transmit power through the cooling substrate 508 and/or to provide a ground connection through the cooling substrate 508.

The interposer 512, which may be made of silicon or another semiconductor, provides electrical conductivity between the first and second processing tiers 516 and 520 and the memory layer 524, on the one hand, and the co-packaged optics 514, on the other. The interposer 512 may also enable electrical communication between the system 500 and other elements mounted on, connected to, or otherwise in electrical communication with the interposer 512 (e.g., Ethernet ports, fiber optic connections, Wi-Fi® transceivers, Bluetooth® modules, and/or cellular communication modules). Additionally, the interposer 512 may provide electrical communication paths and/or otherwise facilitate electrical communication between or among the first processing tier 516, the second processing tier 520, and/or the memory layer 524.

The co-packaged optics 514 generate optical signals based on received electrical signals, and also generate electrical signals based on received optical signals. The purpose of the co-packaged optics 514 is to enable fast, efficient communication between the system 500 and other components of a datacenter such as the datacenter 102, or of any other components of a computing environment in which the system 500 is used. In some embodiments, the co-packaged optics 514 may be or comprise one or more cage receptacle assemblies 600, and may be configured to receive a cable connector such as the cable connector 724. The co-packaged optics 514 may also be or comprise, or be configured to receive, one or more pluggable connectors such as an octal small form factor pluggable (OSFP); a Quad Small Form-factor Pluggable (QSFP) connector, or any other connector (e.g., Small Form Pluggable (SFP), C-Form-factor Pluggable (CFP), and the like).

Each of the first processing tier 516 and the second processing tier 520 comprises one or more processing units, such as one or more GPUs or one or more CPUs. In some embodiments, the system 500 comprises only a single processing tier (e.g., the first processing tier 516). In other embodiments, the system 500 comprises more than two processing tiers (e.g., further comprises a third processing tier, a fourth processing tier, etc.). The first and second processing tiers 516 and 520 may be configured to execute instructions stored in the memory layer 520 and/or received via the co-packaged optics 514, and may also be configured to generate electrical signals for transmission to the memory 520 and/or to datacenter components external to the system 500 via the co-packaged optics 514.

The memory layer or memory die 524 may be or comprise, for example, a High Bandwidth Memory (HBM) stack (e.g. 3D HBM stack), a Dynamic Random Access Memory (DRAM) layer, a Static Random Access Memory (SRAM) layer, and/or a Magnetoresistive Random Access Memory (MRAM) layer. The memory layer 524 stores data, which may in some embodiments include instructions for execution by one or more processors included in the first processing tier 516 and/or the second processing tier 520. The data stored in the memory layer or memory die 524 may be accessed (e.g., read, written, or both) by other components of a datacenter 102 or other computing environment in which the system 500 is used (e.g., via the co-packaged optics 514 and/or the PCB 504). The data stored in the memory layer 524 may also be accessed by the first and/or second processing tiers 516 and 520, whether directly or via the interposer 512.

The cold plate 528 provides top-side cooling to the memory layer 524, to a progressively lesser extent to the second processing tier 520, the first processing tier 516, and so on to the remaining elements of the system 500 from the top of the system 500 stack. The cold plate 528 may be or comprise a thermally conductive material (including any heat transfer material described herein); one or more structures and/or devices configured to improve heat transfer, such as fins and/or fans; and/or one or more channels for routing heat transfer fluid (including any heat transfer fluid described herein), through the cold plate 528. The cold plate may be in thermally conductive communication with one or more of a heat sink, a heat transfer fluid source, and/or one or more additional components useful for extracting heat from the system 500.

Although FIG. 4 depicts the elements of the system 500 arranged in a specific order, in other embodiments of the present disclosure those elements may be arranged differently. For example, in some embodiments, the memory layer 524 may be positioned between the first processing tier 516 and the second processing tier 520. Also in some embodiments, the memory layer 524 may be positioned between the interposer 512 and the first processing tier 516, or between the cooling substrate 508 and the interposer 512. Similarly, the first processing tier 516 may alternatively be positioned between the memory layer 524 and the cold plate 528, or between the cooling substrate 508 and the interposer 512. In some embodiments, the system 500 may comprise a plurality of cooling substrates 508, positioned between other layers of the system 500 (e.g., one positioned between the first processing tier 516 and the second processing tier 520, and/or one positioned between the second processing tier 520 and the memory layer 524). In still further embodiments, the interposer 512 may be positioned underneath the cooling substrate 508, or above the second processing unit 520, or above the memory layer 524.

The system 500 in some embodiments may comprise additional layers (e.g., additional memory layers, additional processing tiers, additional interposers, additional cooling substrates, additional PCBs). In such embodiments, the like layers may be vertically adjacent each other, or may be vertically spaced from each other by unlike layers. The system 500 may also comprise fewer layers. For example, in some embodiments the system 500 may omit the interposer 512, the co-packaged optics 514, and/or the cold plate 528.

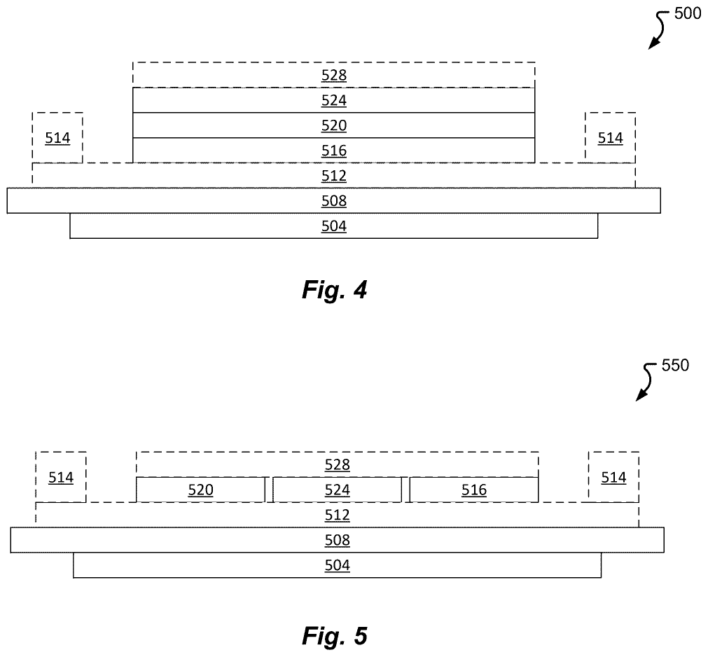

Turning now to FIG. 5, the system 550 comprises a bottom-cooled 2.5D stack. Each of the like-numbered elements of the system 550 has the same function as in the system 500, but instead of the second processing tier 520 being positioned on top of the first processing tier 516, and the memory layer 524 being positioned on top of the second processing tier 520, each of the first processing tier 516, the second processing tier 520, and the memory layer 524 is positioned directly above the interposer 512, and the cold plate 528 is positioned directly on top of each of the first processing tier 516, the second processing tier 520, and the memory layer 524.

The 2.5D configuration of the system 500 enables the cold plate 528 to provide direct top-side cooling to the memory layer 524, the first processing tier 516, and the second processing tier 520. That configuration also places each of the memory layer 524, the first processing tier 516, and the second processing tier 520 in close proximity to the cooling substrate 508 for bottom-side cooling.

Like the system 500, the system 550 in some embodiments may comprise additional layers (e.g., additional memory layers, additional processing tiers, additional interposers, additional cooling substrates). In such embodiments, the like layers may be horizontally and/or vertically adjacent each other, or may be spaced from each other (again, horizontally and/or vertically) by unlike layers. The system 550 may also comprise fewer layers. For example, in some embodiments the system 550 may omit the interposer 512, the co-packaged optics 514, and/or the cold plate 528.

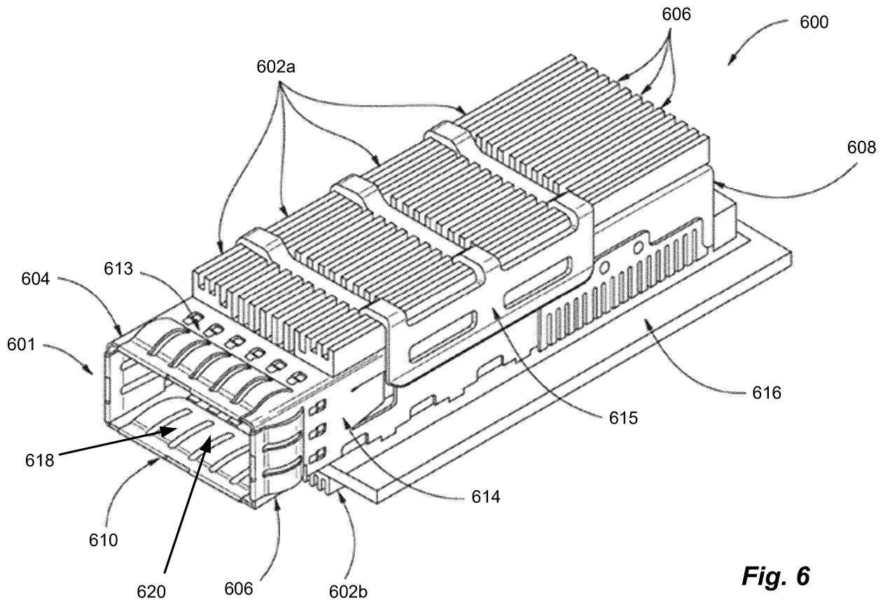

FIG. 6 illustrates one example of a cage receptacle assembly 600 (also referred to herein simply as a cage 600). The cage assembly receptacle assembly 600 is shown to include a cage body 601.

The cage body 601 of the cage 600 may be defined by a top cage member 604 that defines a top portion 613 and two side portions 614 that extend between the top portion 613 of the top cage member 604 to a bottom cage member 606. The top cage member 604 may be configured to attach to the bottom cage member 606 to form the cage body 601. The cage body 601 of the cage 600 may be configured to at least partially receive a cable connector 724 (also referred to herein as a connector plug) as illustrated in FIG. 7A or 7B (e.g., a QSFP cable and/or connector) such that a top surface 728 of the cable connector 724 is disposed proximate the top cage member 604 and a bottom surface 732 of the cable connector 724 is disposed proximate the bottom cage member 606.

The cage 600 may also define a first end 610 and a second end 608 opposite the first end 610, where the first end 610 is configured to receive a cable connector such as the cable connector 724 illustrated in FIGS. 7A-7B. For example, the first end 610 of the cage 600 may be defined such that at least a portion of the cable connector 724 may be inserted into the cage 600, or otherwise brought into engagement or contact with an inner surface 618 of cage body 601 via the first end 610. The first end 610 may be configured to receive a cable connector 724 of any suitable dimension or of any suitable type (e.g., AOC, Ethernet, Direct Attach Copper, etc.) such that the top cage member 604 is located proximate to the top surface 728 of the cable connector 724 and the bottom cage member 606 is located proximate to the bottom surface 732 of the cable connector 724. As a non-limiting example, the first end 610 may be configured to receive a cable connector 724 corresponding to a QSFP cable connector, such that the QSFP is secured to the cage receptacle assembly 600 by engaging at least a part of the inner surface 618 of the cage body 601 via the first end 610.

The cage body 601 may further define a second end 608 opposite the first end 610, where the second end 608 is configured to be received by a module for enabling signals to pass between the cable connector 724 and a module. The cage 600 may be configured to engage, or be secured to, a module (e.g., switch module 312). The cage receptacle assembly 600 may be configured such that the second end 608 defines at least one extension capable of being received by a datacenter switch module 312 (e.g., male to female connection). An opening 620 defined by the cage body 601 of the cage 600 may be such that a cable connector 724 may extend through the cage body 601 of the cage receptacle assembly 600. Specifically, the cable connector 724 may be configured (e.g., sized and shaped) such that upon engagement of the second end 608 of the cage receptacle assembly 600 with the module, the cable connector 724 may also engage the switch module 312 such that signals may be transmitted between the cable connector 724 and switch module 312.

By way of a more particular example, a cable connector 724 may be received by the cage 600 such that at least a portion of the cable connector 724 is supported and/or surrounded by the cage body 601 of the cage 600. Illustratively, cable connector 724 (e.g., the end of a cable configured to engage a module and allow electrical communication therethrough) may be positioned such that when the cage 600 engages the module 312, the cable connector 724 engages a corresponding port of the system to allow signals (e.g., electrical signals, optical signals, or the like) to travel between the connector and the module.

As shown in FIG. 6, the cage receptacle assembly 600 may further include one or more heatsinks, such as a first heatsink 602a and a second heatsink 602b. The first heatsink 602a may be secured to the cage body 601 with a retention mechanism 615, such as a spring clip. The second heatsink 602b may be provided on an opposite side of the cage body 601 from the first heatsink 602a. In some embodiments, the second heatsink 602b is provided on an opposite side of a substrate 616 from the cage body 601 and may be in thermal communication with the cage body 601 through a via formed in the substrate 616. The heatsinks 602a, 602b may help facilitate the transfer of heat away from the cage receptacle assembly 600 and/or the cable connector 724 when the cable connector 724 is inserted into the cage receptacle assembly 600.

Turning now to FIG. 8, an exploded view of a bottom-cooled processing stack 800 (similar to the processing stack of the system 500) is shown. The stack comprises a PCB 804 (which may be the same as or similar to the PCB 504), as well as a cooling substrate 808 (which may be the same as or similar to the cooling substrate 508). The cooling substrate 808 comprises a plurality of manifolds 810, which provide fluid communication with a heat transfer fluid source (not shown). For example, heat transfer fluid may enter the cooling substrate 808 from a fluid source via at least one manifold 810, and after passing through at least a portion of the cooling substrate 808 may exit the cooling substrate 808 via another manifold 810, which may be connected to the same or to a different heat transfer fluid source. In some embodiments, the heat transfer fluid source operates as a heat sink. In other embodiments, the heat transfer fluid may be treated (e.g. cooled) either after exiting the cooling substrate 808 via a manifold 810 or prior to entering the cooling substrate 808 via a manifold 810. In some embodiments, all of the manifolds 810 on one side of the cooling substrate 808 are used as heat transfer fluid inlets, and all of the manifolds 810 on an opposed side of the cooling substrate 808 are used as heat transfer fluid outlets. Although the manifolds 810 are shown in FIG. 8 as being on opposite sides of the cooling substrate 808, embodiments of the present disclosure include cooling substrates 808 with one or more manifolds on one, two, three, and/or four sides of the cooling substrate 808. The cooling substrate thus minimizes pressure drop and cools from four sides.

Heat transfer fluid, as used herein, refers to any liquid or gas heat transfer fluid, such as water, carbon dioxide, ammonia, hydrocarbons, hydrofluoroolefins, hydrofluorocarbons, hydrofluoroethers, air, and/or any combination thereof. The heat transfer fluid may be a fluid that will not harm electronic components if the heat transfer fluid leaks from the cooling substrate (e.g., the cooling substrate 808 or the cooling substrate 508), such as deionized water or another dielectric fluid. The heat transfer fluid may be a water solution (e.g. propylene glycol-water), brine, antifreeze, a mixture of antifreeze and water, oil, alcohol, mercury or the like or any other suitable heat conductive fluid. The heat transfer fluid may be an electrically nonconductive cooling liquid, such as deionized water, a coolant such as R-134a, a mixture of water and additives (e.g., a mixture of water and ethylene glycol, or a mixture of water and propylene glycol (e.g., a 25% concentration of propylene glycol in deionized water). The heat transfer fluid may also be a dielectric fluid alone (e.g., not having water for purposes of this disclosure) or a water in combination with an additive including at least one dielectric fluid, such as or one or more of de-ionized water, ethylene glycol, and propylene glycol. In at least one embodiment, the heat transfer fluid may be a mixed solution containing lithium bromide as the absorbent material and water as the carrier material. The heat transfer fluid may also be a two-phase coolant that has a boiling point that is below the expected operating temperature of the electronic devices. Exemplary two-phase coolants include 2, 3, 3, 3-tetrafluoropropene, 1, 1, 1, 2-tetrafluoroethane and water.

The cooling substrates 508 and 808 may, in some embodiments, utilize heat transfer paths comprising a non-fluidic heat transfer material, such as silver, copper, diamond, graphite, boron nitride, silicon carbide and/or any other thermally conductive material, instead of or in addition to microfluidic channels. In such embodiments, at least a portion of the solid heat transfer material absorbs heat within the cooling substrate, and conducts that heat to a heat sink or other location or device selected and/or configured to remove heat from the heat transfer material.

The processing stack 800 is also depicted to include an interposer 812 with co-packaged optics 814 (which may be the same as or similar to the interposer 512 and co-packaged optics 514, respectively); first and second processing layers 816 and 820 (which may be the same as or similar to the first and second processing tiers 516 and 520, and each comprise a graphics processing unit (GPU), a central processing unit (CPU), and/or another processing unit); a memory layer 824 (which may be the same as or similar to the memory layer or memory die 524); and a cold plate 828 (which may be the same as or similar to the cold plate 528). The cold plate 828 is also shown with manifolds 830, which may be the same as or similar to the manifolds 810 of the cooling substrate 808, and like the manifolds 810, may be positioned (in any number) on opposite sides of the cold plate 828, or in any other configuration around the cold plate 828.

The processing stack 800 having at least one processing unit benefits not just from topside cooling provided by the cold plate 828, but also from bottom-side cooling provided by the cooling substrate 808. As a result, the thermal load generated by the processing stack 800 may be managed more efficiently and/or more effectively than if the processing stack 800 had only topside cooling via the cold plate 828.

Although the processing stack 800 is a 3D processing stack, embodiments of the present disclosure include 2.5D processing stacks (such as the 2.5D processing stack of the system 550) as well. In some embodiments, for example, the processing layers 816 and 820 may be arranged horizontally adjacent to, and on the same plane as, the memory layer 824. In such embodiments, both the interposer 812 and the cold plate 828 may be vertically adjacent to each of the processing layer 816, the processing layer 820, and the memory layer 824.

In some embodiments of the present disclosure, processing stacks such as the systems 500 and 550 as well as the processing stack 800 may not include a cold plate (such as the cold plates 528 and 828) for top-side cooling, and instead may be cooled solely or primarily by a cooling substrate (such as the cooling substrates 508 and 808) providing bottom-side cooling. Also in some embodiments, one or more of the other elements depicted in the systems 500 and 550 and the processing stack 800 may be omitted (e.g., the second processing tier 520 or second processing layer 820; the interposer 512 or 812; and/or the co-packaged optics 514 or 814). In still further embodiments, one or more additional elements not depicted in the systems 500 and 550 and the processing stack 800 may be included (e.g., one or more additional processing tiers or layers, one or more additional memory layers, one or more additional cooling substrates). And in still further embodiments, the layers described in connection with the systems 500 and 500 and the processing stack 800 may be arranged in a different stacking order. Any combination of the foregoing embodiments also falls within the scope of the present disclosure.

Adjacent layers in the systems 500 and 550 and in the processing stack 800 may be bonded or otherwise connected to each other using any method that permits any interoperability required for the systems 500 and 550 and the processing stack 800 to function as intended.

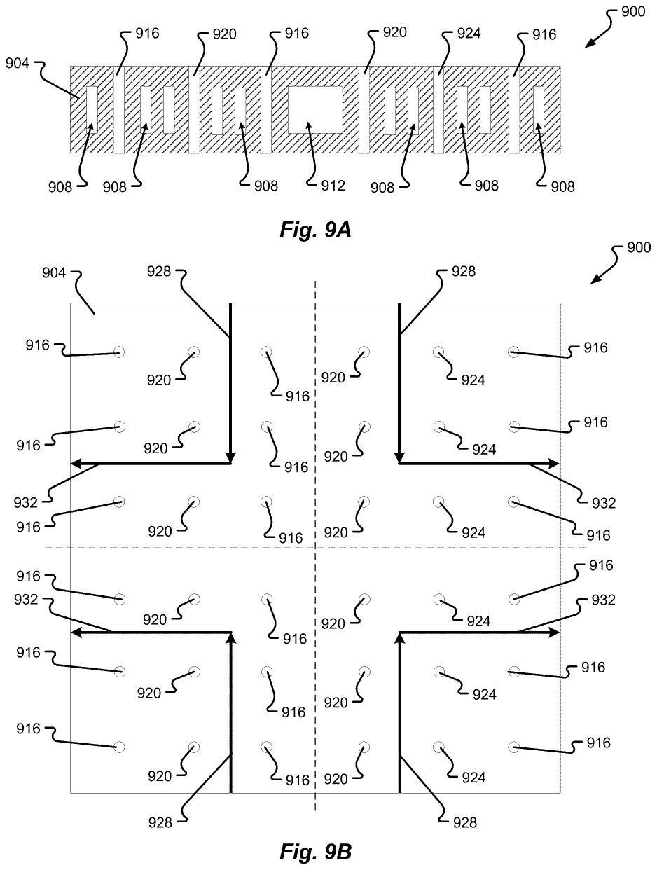

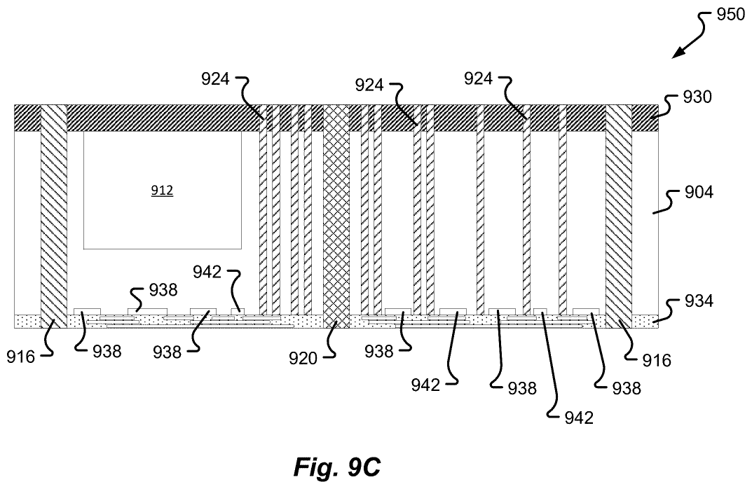

FIGS. 9A-9B provide additional details regarding a cooling substrate 900 (which may be the same as or similar to the cooling substrates 508 and/or 808). The cooling substrate 900 comprises a silicon plate 904, which in other embodiments may be a semiconductor other than silicon. A plurality of microfluidic channels 908 run through the silicon plate 904, each configured to carry a heat transfer fluid through the silicon plate 904. In some embodiments, the microfluidic channels 908 carry heat transfer fluid from a first side of the silicon plate 904 to a second side of the silicon plate 904 opposite the first side. In the embodiment of FIGS. 9A-9B, however, the microfluidic channels 908 carry heat transfer fluid from a first side of the silicon plate 904 toward an opposite side of the silicon plate 904 along a path 928, before the channels 908 make a perpendicular turn so as to carry the heat transfer fluid along an outlet path 932 toward an adjacent side of the silicon plate 904 (e.g., a side adjacent the first side of the silicon plate 904). This arrangement allows for the circulation of fresh heat transfer fluid (e.g., heat transfer fluid that has not already been heated by passing through a different portion of the silicon plate 904) into each quadrant of the silicon plate 904.

In other embodiments, each microfluidic channel 908 may follow a path that is non-parallel with one or more adjacent microfluidic channels. For example, one microfluidic channel may extend from a first side of the silicon plate 904 to a second, opposite side of the silicon plate 904, while an adjacent microfluidic channel may extend from the first side of the silicon plate 904 to a third side of the silicon plate 904 adjacent the first and/or second sides.

The microfluidic channels 908 may, in some embodiments, be linear, while in other embodiments the microfluidic channels may be curvilinear. The microfluidic channels 908 may all have the same cross-sectional area, or one or more of the microfluidic channels 908 may have a larger or smaller cross-sectional area than others of the microfluidic channels. The cross-sectional area of a given microfluidic channel may be selected based on the total length of the channel and/or the heat transfer requirements of the channel (e.g., a longer channel or a channel that runs beneath a significant heat source may have a greater cross-sectional area to allow more heat transfer fluid to flow therethrough, while a shorter channel and/or a channel that does not pass beneath a significant heat source may have a smaller cross-sectional area given a reduced need for the transfer of heat to heat transfer fluid flowing therethrough). In still further embodiments, the cross-sectional area of a microfluidic channel 908 may be determined based in whole or in part upon the space available within the silicon plate 904 for the channel, taking into account any minimum separation distance between the microfluidic channel and other components of the cooling substrate 900 such as the TSVs (e.g., to reduce or minimize the likelihood that heat transfer fluid could leak out of a microfluidic channel 908 and/or cause a wall of the microfluidic channel 908 to fail, either of which scenarios could have negative implications for electrical components or pathways that come into contact with the heat transfer fluid).

All of the microfluidic channels 908 may be in fluid communication with each other within the cooling substrate 900, or all of the microfluidic channels 908 may be in fluid communication with each other via a common heat transfer fluid source. In other embodiments, one or more of the microfluidic channels 908 may be connected to a first heat transfer fluid source, and one or more other microfluidic channels 908 may be connected to a second and/or additional heat transfer fluid sources, such that not all of the microfluidic channels 908 are in fluid communication with each other.

The cooling substrate 900 also comprises a microfluidic channel 912. The microfluidic channel 912 has a larger cross-sectional area than the microfluidic channels 908, and therefore is configured to allow a greater flow of heat transfer fluid therethrough. Any of the reasons described above for increasing the cross-sectional area of a microfluidic channel 908 may be used to justify the inclusion of a microfluidic channel 912. In some embodiments, the microfluidic channel 912 may define a single, linear path through the silicon plate 904, or the microfluidic channel 912 may define a curvilinear path through the silicon plate 904, or the microfluidic channel 912 may extend parallel to the paths 928 and 932, such that heat transfer fluid entering the microfluidic channel 912 moves toward an opposite side of the silicon plate 904 before turning and existing the silicon plate 904 via an outlet path perpendicular to the inlet path.

One or more of the microfluidic channels 908 and 912 of the cooling substrate 900 may, in some embodiments, be replaced with a solid heat transfer material. In such embodiments, the solid heat transfer material absorbs heat from components adjacent and/or near to the cooling substrate 900, and conducts that heat away from such components.

The cooling substrate 900 further comprises a plurality of TSVs for enabling electrical conductivity from a top side of the cooling substrate 900 to a bottom side of the cooling substrate 900, or vice versa. The TSVs 916 are power TSVs, while the TSVs 920 are ground TSVs and the TSVs 924 are signal TSVs. The power TSVs 916 and the ground TSVs 920 ensure that other components of a processing stack in which the cooling substrate 900 is utilized may be safely powered, even if the cooling substrate 900 is located between the power source and the powered component. The signal TSVs 924 allow electrical signals to be communicated through the cooling substrate 900, for example when the source of the electrical signals is located on one side of (e.g., above) the cooling substrate 900 and the destination of the electrical signals is located on an opposite side of (e.g., below) the cooling substrate 900.

Although the cooling substrate 900 as depicted in FIGS. 9A-9B comprises 18 power TSVs 916, 12 ground TSVs 920, and six signal TSVs 924, more or fewer TSVs may be included in a cooling substrate according to embodiments of the present disclosure. Additionally, while the cooling substrate 900 comprises TSVs arranged in rows and columns, with each column of TSVs having only a single type of TSV (e.g., power TSVs 916, or ground TSVs 920, or signal TSVs 924), in other embodiments of the present disclosure any given row of TSVs and/or any given column of TSVs may comprise one or multiple types of TSV.

The TSVs 916, 920, and 924 of the cooling substrate 900 have a diameter of 25 micrometers, and are spaced from adjacent TSVs in the same row and column by a pitch of 150 micrometers (e.g., from the center of one TSV to the center of the adjacent TSV). TSVs according to other embodiments of the present disclosure may have a diameter of 20 micrometers, or of 21 micrometers, or of 22 micrometers, or of 23 micrometers, or of 24 micrometers, or of 26 micrometers, or of 27 micrometers, or of 28 micrometers, or of 29 micrometers, or of 30 micrometers, or between 20 and 30 micrometers, or within any subrange that falls within 20 and 30 micrometers. Also, TSVs according to other embodiments of the present disclosure may be spaced from adjacent TSVs in the same row and/or column by a pitch (e.g., the distance between the centers of two adjacent TSVs) of 70 micrometers, or of 80 micrometers, or of 90 micrometers, or of 100 micrometers, or of 110 micrometers, or of 120 micrometers, or of 130 micrometers, or of 140 micrometers, or of 160 micrometers, or of 170 micrometers, or of 180 micrometers, or of 190 micrometers, or of 200 micrometers, or between 70 and 200 micrometers, or within any subrange that falls within 70 and 200 micrometers.

FIG. 9C depicts a cooling substrate 950 (which may be similar to the cooling substrates 508 and/or 808). The cooling substrate 900 comprises a silicon plate 904, sandwiched between a bonding layer 930 and metal layers 934. A single microfluidic channel 912 runs through the silicon plate 904, and is configured to carry a heat transfer fluid through the silicon plate 904.

The cooling substrate 950 also comprises a plurality of power TSVs 916, a single ground TSV 920, and a plurality of signal TSVs 924, each of which has the same or a substantially similar function as the corresponding components of the cooling substrate 900. Additionally, a plurality of gates 938 and decoupling capacitors 942 are provided at the boundary between the silicon plate 904 and the metal layers 934. In the embodiment of FIG. 9C, the power TSVs 916 have a diameter of 10 micrometers, the pitch between the power TSVs 916 and the ground TSV 920 is 100 micrometers, the bonding layer 930 has a thickness of 10 micrometers, the silicon plate 904 has a thickness of 60 micrometers, and the metal layers 934 have a combined thickness of 6 micrometers.

In some embodiments of the present disclosure, not every type of TSV has the same diameter, while in other embodiments, not every TSV of the same type has the same diameter. Similarly, in some embodiments of the present disclosure, the pitch between adjacent TSVs in the same row and/or column may vary.

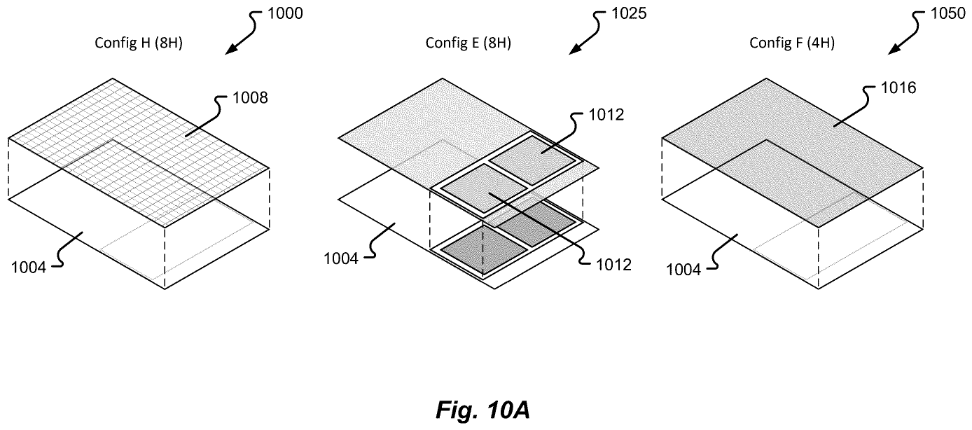

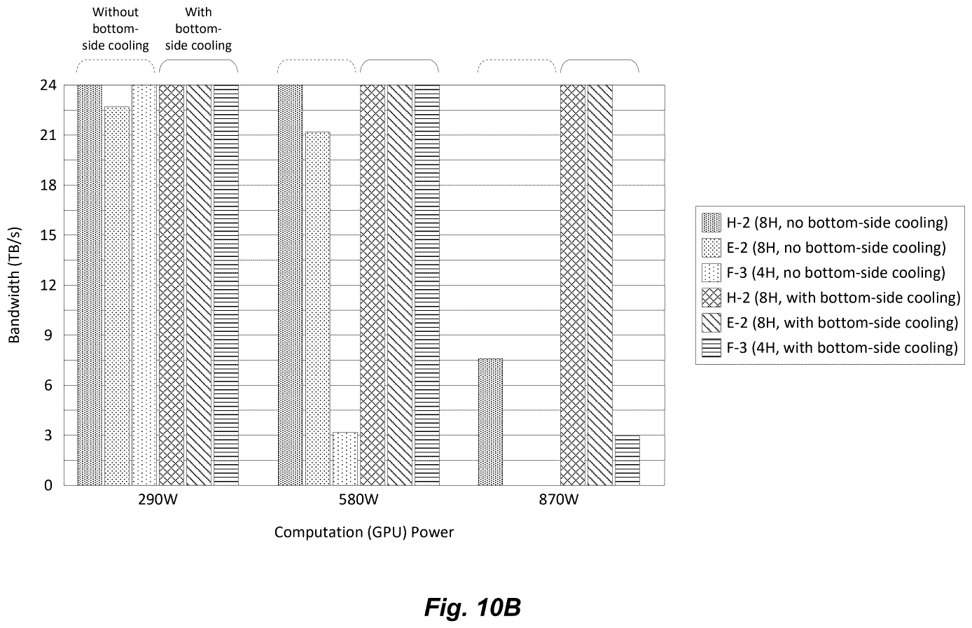

Turning now to FIGS. 10A-B, numerous computational fluid dynamics (CFD) studies have been conducted to investigate the ability of a microfluidic cooling substrate to effectively remove heat, lower the overall temperature of the stack, and improve computational performance. FIG. 10A shows three different 3D stack configurations investigated. The stack 1000, referred to as Config H (8H), comprises a processing or GPU layer 1004, and a high-bandwidth memory (HBM) layer 1008 comprising eight DRAM layers (denoted by 8H) stacked on top of the GPU layer 1004. In the HBM layer 1008, strips of HBM are interleaved with pure silicon, so that only approximately 50% of the GPU footprint is covered.

The stack 1025, referred to as Config E (8H), comprises two HBM stacks 1012 covering only part of the footprint of the processing or GPU layer 1004.

The stack 1050, referred to as Config F (4H), comprises an HBM layer 1016 comprising four DRAM layers (denoted by 4H) stacked on top of, and covering the entire footprint of, the GPU layer 1004.

The various stacks were studied in order to investigate the impact of the differing coverage of the HBM layers over the GPU layer on the ability to maintain the GPU junction temperature at 105° C. or below, and the maximum HBM temperature at 95° C. or below.

FIG. 10B shows the results. Note that study was conducted both without and with the bottom-side cooling provided by a microfluidic cooling substrate such as the cooling substrates 508, 808, 900, and 950 disclosed herein. For the study that included the cooling substrate, the selected boundary condition assumed a modest heat transfer coefficient of 10,000 W/m2-K, which in turn translates to a very low coolant flow rate through the microfluidic cooling substrate. (A low flow rate through the microfluidic substrate is important given the micrometer-sized flow passages of the substrate.) The results clearly show the benefit of the microfluidic substrate, with the best results obtained with Config H 1000 and Config E 1025, both of which have HBM coverage that does not span the full footprint of the GPU layer 1004. As shown in the rightmost columns, these configurations achieved 870 W of GPU power assuming 45° C. PG25(25 % propylene glycol/water mix), at full memory bandwidth of 24 TB/s. Thus, adding bottom-side cooling (which lowers the T_{j,max} by about 10° C.) enables a higher GPU power with HBM run at full bandwidth of 24 TB/s.

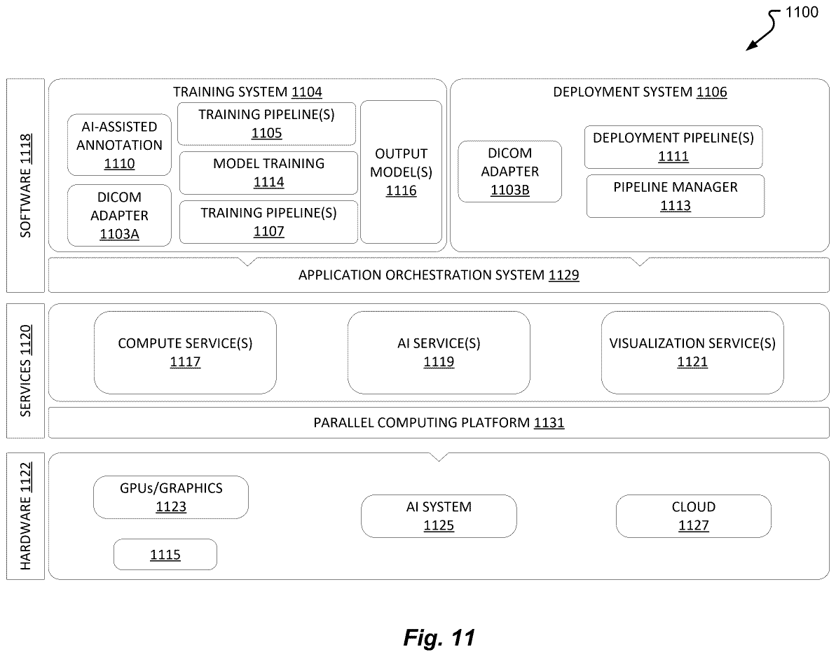

FIG. 11 is a system diagram for an example system 1100 for generating and deploying an imaging deployment pipeline, in accordance with at least one embodiment. In at least one embodiment, system 1100 may be used to implement one or more processes including advanced processing and inferencing pipelines. In at least one embodiment, system 1100 may include training system 1104 and deployment system 1106. In at least one embodiment, training system 1104 and deployment system 1106 may be implemented using software 1118, services 1120, and/or hardware 1122, as described herein.

In at least one embodiment, system 1100 (e.g., training system 1104 and/or deployment system 1106) may be implemented in a cloud computing environment (e.g., using cloud 1127). In at least one embodiment, system 1100 may be implemented locally, or as a combination of both cloud and local computing resources. In at least one embodiment, access to APIs in cloud 1127 may be restricted to authorized users through enacted security measures or protocols. In at least one embodiment, a security protocol may include web tokens that may be signed by an authentication (e.g., AuthN, AuthZ, Gluecon, etc.) service and may carry appropriate authorization. In at least one embodiment, APIs of virtual instruments (described herein), or other instantiations of system 1100, may be restricted to a set of public IPs that have been vetted or authorized for interaction.

In at least one embodiment, various components of system 1100 may communicate between and among one another using any of a variety of different network types, including but not limited to local area networks (LANs) and/or wide area networks (WANs) via wired and/or wireless communication protocols. In at least one embodiment, communication between facilities and components of system 1100 (e.g., for transmitting inference requests, for receiving results of inference requests, etc.) may be communicated over a data bus or data busses, wireless data protocols (Wi-Fi), wired data protocols (e.g., Ethernet), etc.

In at least one embodiment, a software layer may be implemented as a secure, encrypted, and/or authenticated API through which applications or containers may be invoked (e.g., called) from an external environment(s). In at least one embodiment, applications may then call or execute one or more services 1120 for performing compute, AI, or visualization tasks associated with respective applications, and software 1118 and/or services 1120 may leverage hardware 1122 to perform processing tasks in an effective and efficient manner.

In at least one embodiment, software 1118 and/or services 1120 may be optimized for GPU processing with respect to deep learning, machine learning, and/or high-performance computing, as non-limiting examples. In at least one embodiment, at least some of computing environment of deployment system 1106 and/or training system 1104 may be executed in a datacenter one or more supercomputers or high performance computing systems, with GPU optimized software (e.g., hardware and software combination of NVIDIA's DGX system). In at least one embodiment, datacenters may be compliant with provisions of HIPAA, such that receipt, processing, and transmission of imaging data and/or other patient data is securely handled with respect to privacy of patient data. In at least one embodiment, hardware 1122 may include any number of GPUs that may be called upon to perform processing of data in parallel, as described herein. In at least one embodiment, cloud platform may further include GPU processing for GPU-optimized execution of deep learning tasks, machine learning tasks, or other computing tasks. In at least one embodiment, cloud platform (e.g., NVIDIA's NGC) may be executed using an AI/deep learning supercomputer(s) and/or GPU-optimized software (e.g., as provided on NVIDIA's DGX systems) as a hardware abstraction and scaling platform. In at least one embodiment, cloud platform may integrate an application container clustering system or orchestration system (e.g., KUBERNETES) on multiple GPUs to enable seamless scaling and load balancing.

The hardware 1122 may also include inference and/or training logic 1115. In at least one embodiment, the inference and/or training logic 1115 of at least one processor may be part of a building management system (BMS) for outlet quality factor stabilization of two-phase fluid for a datacenter cooling system. In at least one embodiment, a determination to engage a certain feature of a stabilizing subsystem and a flow controller may be provided to one or more neural networks of an inference and/or training logic 1115 to cause one or more neural networks to infer which feature and which flow controllers to gracefully engage or disengage.

In at least one embodiment, training system 1104 may execute training pipelines 1105. In at least one embodiment, where one or more machine learning models are to be used in deployment pipelines 1111 by deployment system 1106, training pipelines 1105 may be used to train or retrain one or more pre-trained models, and/or implement one or more pre-trained models (e.g., without a need for retraining or updating). In at least one embodiment, as a result of training pipelines 1105, output model(s) 1116 may be generated. In at least one embodiment, training pipelines 1105 may include any number of processing steps, such as but not limited to imaging data (or other input data) conversion or adaption In at least one embodiment, for different machine learning models used by deployment system 1106, different training pipelines 1105 may be used. In at least one embodiment, any combination of tasks within training system 1104 may be used depending on what is required for each respective machine learning model. In at least one embodiment, one or more of machine learning models may already be trained and ready for deployment so machine learning models may not undergo any processing by training system 1104, and may be implemented by deployment system 1106.

The training system 1104 comprises a DICOM adapter 1103A, and the deployment system 1106 comprises a DICOM adapter 1103B. The DICOM adapters translate data between different protocols to enable interoperability between DICOM-compliant and non-DICOM-compliant systems. The DICOM adapters may be, for example, NVIDIA Clara^{TM} DICOM adapters.

In at least one embodiment, output model(s) 1116 and/or pre-trained model(s) 1107 may include any types of machine learning models depending on implementation or embodiment. In at least one embodiment, and without limitation, machine learning models used by system 1100 may include machine learning model(s) using linear regression, logistic regression, decision trees, support vector machines (SVM), Naïve Bayes, k-nearest neighbor (Knn), K means clustering, random forest, dimensionality reduction algorithms, gradient boosting algorithms, neural networks (e.g., auto-encoders, convolutional, recurrent, perceptrons, Long/Short Term Memory (LS™), Hopfield, Boltzmann, deep belief, deconvolutional, generative adversarial, liquid state machine, etc.), and/or other types of machine learning models.

In at least one embodiment, training system 1104 and/or training pipelines 1105 may include AI-assisted annotation 1110. In at least one embodiment, labeled data (e.g., traditional annotation) may be generated by any number of techniques. In at least one embodiment, labels or other annotations may be generated within a drawing program (e.g., an annotation program), a computer-aided design (CAD) program, a labeling program, another type of program suitable for generating annotations or labels for ground truth, and/or may be hand drawn, in some examples. In at least one embodiment, ground truth data may be synthetically produced (e.g., generated from computer models or renderings), real produced (e.g., designed and produced from real-world data), machine-automated (e.g., using feature analysis and learning to extract features from data and then generate labels), human annotated (e.g., labeler, or annotation expert, defines location of labels), and/or a combination thereof. In at least one embodiment, for each instance of data or data type used by machine learning models, there may be corresponding ground truth data generated by training system 1104. In at least one embodiment, AI-assisted annotation may be performed as part of deployment pipelines 1111; either in addition to, or in lieu of AI-assisted annotation included in training pipelines 1105.

In at least one embodiment, deployment system 1106 may execute deployment pipelines 1111. In at least one embodiment, deployment pipelines 1111 may include any number of applications that may be sequentially, non-sequentially, or otherwise applied to data and/or data types. In at least one embodiment, as described herein, a deployment pipeline 1111 for an individual device may be referred to as a virtual instrument for a device. In at least one embodiment, for a single device, there may be more than one deployment pipeline 1111 depending on information desired from data generated by a device.

In at least one embodiment, an image generation application may include a processing task that includes use of a machine learning model. In at least one embodiment, a user may desire to use their own machine learning model, or to select a machine learning model from an existing model registry. In at least one embodiment, a user may implement their own machine learning model or select a machine learning model for inclusion in an application for performing a processing task. In at least one embodiment, applications may be selectable and customizable, and by defining constructs of applications, deployment and implementation of applications for a particular user are presented as a more seamless user experience. In at least one embodiment, by leveraging other features of system 1100—such as services 1120 and hardware 1122—deployment pipelines 1111 may be even more user friendly, provide for easier integration, and produce more accurate, efficient, and timely results.

In at least one embodiment, deployment system 1106 may include a user interface 1414 (e.g., a graphical user interface, a web interface, etc.) that may be used to select applications for inclusion in deployment pipeline(s) 1111, arrange applications, modify or change applications or parameters or constructs thereof, use and interact with deployment pipeline(s) 1111 during set-up and/or deployment, and/or to otherwise interact with deployment system 1106. In at least one embodiment, although not illustrated with respect to training system 1104, user interface 1414 (or a different user interface) may be used for selecting models for use in deployment system 1106, for selecting models for training, or retraining, in training system 1104, and/or for otherwise interacting with training system 1104.

In at least one embodiment, pipeline manager 1113 may be used, in addition to an application orchestration system 1129, to manage interaction between applications or containers of deployment pipeline(s) 1111 and services 1120 and/or hardware 1122. In at least one embodiment, pipeline manager 1113 may be configured to facilitate interactions from application to application, from application to service 1120, and/or from application or service to hardware 1122. In at least one embodiment, although illustrated as included in software 1118, this is not intended to be limiting, and in some examples pipeline manager 1113 may be included in services 1120. In at least one embodiment, application orchestration system 1129 (e.g., Kubernetes, DOCKER, etc.) may include a container orchestration system that may group applications into containers as logical units for coordination, management, scaling, and deployment. In at least one embodiment, by associating applications from deployment pipeline(s) 1111 (e.g., a reconstruction application, a segmentation application, etc.) with individual containers, each application may execute in a self-contained environment (e.g., at a kernel level) to increase speed and efficiency.

In at least one embodiment, each application and/or container (or image thereof) may be individually developed, modified, and deployed (e.g., a first user or developer may develop, modify, and deploy a first application and a second user or developer may develop, modify, and deploy a second application separate from a first user or developer), which may allow for focus on, and attention to, a task of a single application and/or container(s) without being hindered by tasks of another application(s) or container(s). In at least one embodiment, communication, and cooperation between different containers or applications may be aided by pipeline manager 1113 and application orchestration system 1129. In at least one embodiment, so long as an expected input and/or output of each container or application is known by a system (e.g., based on constructs of applications or containers), application orchestration system 1129 and/or pipeline manager 1113 may facilitate communication among and between, and sharing of resources among and between, each of applications or containers. In at least one embodiment, because one or more of applications or containers in deployment pipeline(s) 1111 may share same services and resources, application orchestration system 1129 may orchestrate, load balance, and determine sharing of services or resources between and among various applications or containers. In at least one embodiment, a scheduler may be used to track resource requirements of applications or containers, current usage or planned usage of these resources, and resource availability. In at least one embodiment, a scheduler may thus allocate resources to different applications and distribute resources between and among applications in view of requirements and availability of a system. In some examples, a scheduler (and/or other component of application orchestration system 1129) may determine resource availability and distribution based on constraints imposed on a system (e.g., user constraints), such as quality of service (QoS), urgency of need for data outputs (e.g., to determine whether to execute real-time processing or delayed processing), etc.

In at least one embodiment, services 1120 leveraged by and shared by applications or containers in deployment system 1106 may include compute services 1117, AI services 1119, visualization services 1121, and/or other service types. In at least one embodiment, applications may call (e.g., execute) one or more of services 1120 to perform processing operations for an application. In at least one embodiment, compute services 1117 may be leveraged by applications to perform super-computing or other high-performance computing (HPC) tasks. In at least one embodiment, compute service(s) 1117 may be leveraged to perform parallel processing (e.g., using a parallel computing platform 1131) for processing data through one or more of applications and/or one or more tasks of a single application, substantially simultaneously. In at least one embodiment, parallel computing platform 1131 (e.g., NVIDIA's CUDA) may enable general purpose computing on GPUs (GPGPU) (e.g., GPUs 1123). In at least one embodiment, a software layer of parallel computing platform 1131 may provide access to virtual instruction sets and parallel computational elements of GPUs, for execution of compute kernels. In at least one embodiment, parallel computing platform 1131 may include memory and, in some embodiments, a memory may be shared between and among multiple containers, and/or between and among different processing tasks within a single container. In at least one embodiment, inter-process communication (IPC) calls may be generated for multiple containers and/or for multiple processes within a container to use same data from a shared segment of memory of parallel computing platform 1131 (e.g., where multiple different stages of an application or multiple applications are processing same information). In at least one embodiment, rather than making a copy of data and moving data to different locations in memory (e.g., a read/write operation), same data in same location of a memory may be used for any number of processing tasks (e.g., at a same time, at different times, etc.). In at least one embodiment, as data is used to generate new data as a result of processing, this information of a new location of data may be stored and shared between various applications. In at least one embodiment, location of data and a location of updated or modified data may be part of a definition of how a payload is understood within containers.

In at least one embodiment, AI services 1119 may be leveraged to perform inferencing services for executing machine learning model(s) associated with applications (e.g., tasked with performing one or more processing tasks of an application). In at least one embodiment, AI services 1119 may leverage AI system 1125 to execute machine learning model(s) (e.g., neural networks, such as CNNs) for segmentation, reconstruction, object detection, feature detection, classification, and/or other inferencing tasks. In at least one embodiment, applications of deployment pipeline(s) 1111 may use one or more of output models 1116 from training system 1104 and/or other models of applications to perform inference on imaging data. In at least one embodiment, two or more examples of inferencing using application orchestration system 1129 (e.g., a scheduler) may be available. In at least one embodiment, a first category may include a high priority/low latency path that may achieve higher service level agreements, such as for performing inference on urgent requests during an emergency, or for a radiologist during diagnosis. In at least one embodiment, a second category may include a standard priority path that may be used for requests that may be non-urgent or where analysis may be performed at a later time. In at least one embodiment, application orchestration system 1129 may distribute resources (e.g., services 1120 and/or hardware 1122) based on priority paths for different inferencing tasks of AI services 1119.

In at least one embodiment, shared storage may be mounted to AI services 1119 within system 1100. In at least one embodiment, shared storage may operate as a cache (or other storage device type) and may be used to process inference requests from applications. In at least one embodiment, when an inference request is submitted, a request may be received by a set of API instances of deployment system 1106, and one or more instances may be selected (e.g., for best fit, for load balancing, etc.) to process a request. In at least one embodiment, to process a request, a request may be entered into a database, a machine learning model may be located from a model registry if not already in a cache, a validation step may ensure appropriate machine learning model is loaded into a cache (e.g., shared storage), and/or a copy of a model may be saved to a cache. In at least one embodiment, a scheduler (e.g., of pipeline manager 1113) may be used to launch an application that is referenced in a request if an application is not already running or if there are not enough instances of an application. In at least one embodiment, if an inference server is not already launched to execute a model, an inference server may be launched. Any number of inference servers may be launched per model. In at least one embodiment, in a pull model, in which inference servers are clustered, models may be cached whenever load balancing is advantageous. In at least one embodiment, inference servers may be statically loaded in corresponding, distributed servers.

In at least one embodiment, inferencing may be performed using an inference server that runs in a container. In at least one embodiment, an instance of an inference server may be associated with a model (and optionally a plurality of versions of a model). In at least one embodiment, if an instance of an inference server does not exist when a request to perform inference on a model is received, a new instance may be loaded. In at least one embodiment, when starting an inference server, a model may be passed to an inference server such that a same container may be used to serve different models so long as inference server is running as a different instance.

In at least one embodiment, during application execution, an inference request for a given application may be received, and a container (e.g., hosting an instance of an inference server) may be loaded (if not already), and a start procedure may be called. In at least one embodiment, pre-processing logic in a container may load, decode, and/or perform any additional pre-processing on incoming data (e.g., using a CPU(s) and/or GPU(s)). In at least one embodiment, once data is prepared for inference, a container may perform inference as necessary on data. In at least one embodiment, this may include a single inference call on one piece or set of data, or may require inference on hundreds of pieces or sets of data. In at least one embodiment, an application may summarize results before completing. In at least one embodiment, different models or applications may be assigned different priorities. For example, some models may have a real-time (TAT<1 min) priority while others may have lower priority (e.g., TAT<10 min). In at least one embodiment, model execution times may be measured from requesting institution or entity and may include partner network traversal time, as well as execution on an inference service.

In at least one embodiment, transfer of requests between services 1120 and inference applications may be hidden behind a software development kit (SDK), and robust transport may be provide through a queue. In at least one embodiment, a request will be placed in a queue via an API for an individual application/tenant ID combination and an SDK will pull a request from a queue and give a request to an application. In at least one embodiment, a name of a queue may be provided in an environment from where an SDK will pick it up. In at least one embodiment, asynchronous communication through a queue may be useful as it may allow any instance of an application to pick up work as it becomes available. Results may be transferred back through a queue, to ensure no data is lost. In at least one embodiment, queues may also provide an ability to segment work, as highest priority work may go to a queue with most instances of an application connected to it, while lowest priority work may go to a queue with a single instance connected to it that processes tasks in an order received. In at least one embodiment, an application may run on a GPU-accelerated instance generated in cloud 1127, and an inference service may perform inferencing on a GPU.

In at least one embodiment, visualization services 1121 may be leveraged to generate visualizations for viewing outputs of applications and/or deployment pipeline(s) 1111. In at least one embodiment, GPUs 1123 may be leveraged by visualization services 1121 to generate visualizations. In at least one embodiment, rendering effects, such as ray-tracing, may be implemented by visualization services 1121 to generate higher quality visualizations. In at least one embodiment, visualizations may include, without limitation, 2D image renderings, 3D volume renderings, 3D volume reconstruction, 2D tomographic slices, virtual reality displays, augmented reality displays, etc. In at least one embodiment, virtualized environments may be used to generate a virtual interactive display or environment (e.g., a virtual environment) for interaction by users of a system. In at least one embodiment, visualization services 1121 may include an internal visualizer, cinematics, and/or other rendering or image processing capabilities or functionality (e.g., ray tracing, rasterization, internal optics, etc.).

In at least one embodiment, hardware 1122 may include GPUs 1123, AI system 1125, cloud 1127, and/or any other hardware used for executing training system 1104 and/or deployment system 1106. In at least one embodiment, GPUs 1123 (e.g., NVIDIA's TESLA and/or QUADRO GPUs) may include any number of GPUs that may be used for executing processing tasks of compute services 1117, AI services 1119, visualization services 1121, other services, and/or any of features or functionality of software 1118. For example, with respect to AI services 1119, GPUs 1123 may be used to perform pre-processing on imaging data (or other data types used by machine learning models), post-processing on outputs of machine learning models, and/or to perform inferencing (e.g., to execute machine learning models). In at least one embodiment, cloud 1127, AI system 1125, and/or other components of system 1100 may use GPUs 1123. In at least one embodiment, cloud 1127 may include a GPU-optimized platform for deep learning tasks. In at least one embodiment, AI system 1125 may use GPUs, and cloud 1127—or at least a portion tasked with deep learning or inferencing—may be executed using one or more AI systems 1125. As such, although hardware 1122 is illustrated as discrete components, this is not intended to be limiting, and any components of hardware 1122 may be combined with, or leveraged by, any other components of hardware 1122.

In at least one embodiment, AI system 1125 may include a purpose-built computing system (e.g., a super-computer or an HPC) configured for inferencing, deep learning, machine learning, and/or other artificial intelligence tasks. In at least one embodiment, AI system 1125 (e.g., NVIDIA's DGX) may include GPU-optimized software (e.g., a software stack) that may be executed using a plurality of GPUs 1123, in addition to CPUs, RAM, storage, and/or other components, features, or functionality. In at least one embodiment, one or more AI systems 1125 may be implemented in cloud 1127 (e.g., in a data center) for performing some or all of AI-based processing tasks of system 1100.

In at least one embodiment, cloud 1127 may include a GPU-accelerated infrastructure (e.g., NVIDIA's NGC) that may provide a GPU-optimized platform for executing processing tasks of system 1100. In at least one embodiment, cloud 1127 may include an AI system(s) 1125 for performing one or more of AI-based tasks of system 1100 (e.g., as a hardware abstraction and scaling platform). In at least one embodiment, cloud 1127 may integrate with application orchestration system 1129 leveraging multiple GPUs to enable seamless scaling and load balancing between and among applications and services 1120. In at least one embodiment, cloud 1127 may be tasked with executing at least some of services 1120 of system 1100, including compute services 1117, AI services 1119, and/or visualization services 1121, as described herein. In at least one embodiment, cloud 1127 may perform small and large batch inference (e.g., executing NVIDIA's TENSOR RT), provide an accelerated parallel computing API and platform 1131 (e.g., NVIDIA's CUDA), execute application orchestration system 1129 (e.g., KUBERNETES), provide a graphics rendering API and platform (e.g., for ray-tracing, 2D graphics, 3D graphics, and/or other rendering techniques to produce higher quality cinematics), and/or may provide other functionality for system 1100.

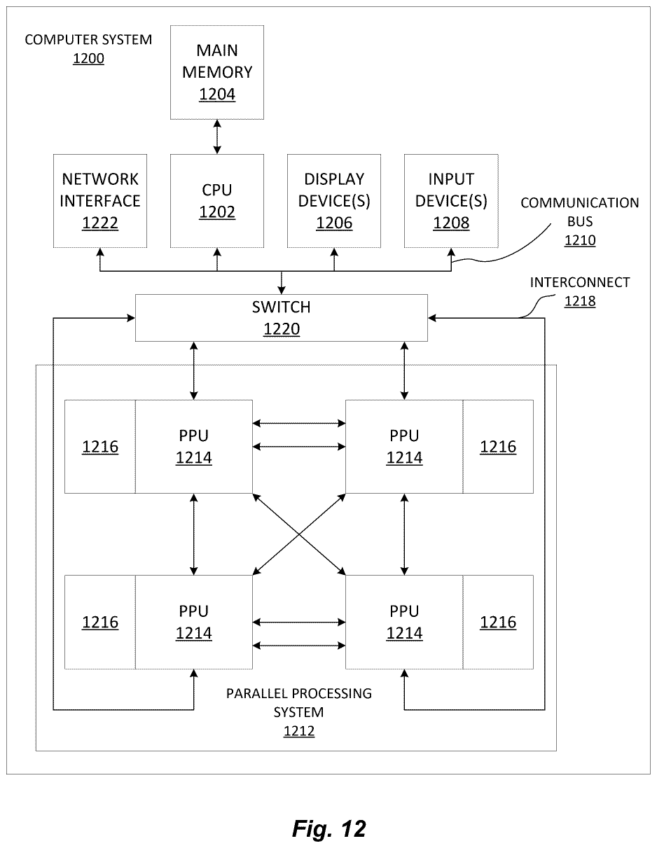

FIG. 12 illustrates a computer system 1200, according to at least one embodiment. In at least one embodiment, computer system 1200 is configured to implement various processes and methods described throughout this disclosure.

In at least one embodiment, computer system 1200 comprises, without limitation, at least one central processing unit (“CPU”) 1202 that is connected to a communication bus 1210 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1200 includes, without limitation, a main memory 1204 and control logic (e.g., implemented as hardware, software, or a combination thereof) and data are stored in main memory 1204 which may take form of random access memory (“RAM”). In at least one embodiment, a network interface subsystem (“network interface”) 1222 provides an interface to other computing devices and networks for receiving data from and transmitting data to other systems from computer system 1200.

In at least one embodiment, computer system 1200, includes, without limitation, input devices 1208, parallel processing system 1212, and display devices 1206 which can be implemented using a conventional cathode ray tube (“CRT”), liquid crystal display (“LCD”), light emitting diode (“LED”), plasma display, or other suitable display technologies. In at least one embodiment, user input is received from input devices 1208 such as keyboard, mouse, touchpad, microphone, and more. In at least one embodiment, each of the foregoing modules can be situated on a single semiconductor platform to form a processing system.

In at least one embodiment, computer programs in the form of machine-readable executable code or computer control logic algorithms are stored in main memory 1204 and/or secondary storage. Computer programs, if executed by one or more processors, enable system 1200 to perform various functions in accordance with at least one embodiment. Memory 1204, secondary storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, the architecture and/or functionality of various is/are implemented in the context of CPU 1202; parallel processing system 1212; an integrated circuit capable of at least a portion of capabilities of both CPU 1202 and parallel processing system 1212; a chipset (e.g., a group of integrated circuits designed to work and sold as a unit for performing related functions, etc.); and any suitable combination of integrated circuit(s).

In at least one embodiment, the architecture and/or functionality of various figures described herein is/are implemented in the context of a general computer system, a circuit board system, a game console system dedicated for entertainment purposes, an application-specific system, and more. In at least one embodiment, computer system 1200 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1212 includes, without limitation, a plurality of parallel processing units (“PPUs”) 1216 and associated memories 1216. In at least one embodiment, PPUs 1216 are connected to a host processor or other peripheral devices via an interconnect 1218 and a switch 1220 or multiplexer. In at least one embodiment, parallel processing system 1212 distributes computational tasks across PPUs 1216 which can be parallelizable—for example, as part of a distribution of computational tasks across multiple graphics processing unit (“GPU”) thread blocks. In at least one embodiment, memory is shared and accessible (e.g., for read and/or write access) across some or all of PPUs 1216, although such shared memory may incur performance penalties relative to the use of local memory and registers resident to a PPU 1216. In at least one embodiment, operation of PPUs 1216 is synchronized through use of a command such as syncthreads( ), which requires all threads in a block (e.g., executed across multiple PPUs 1216) to reach a certain point of execution of code before proceeding.

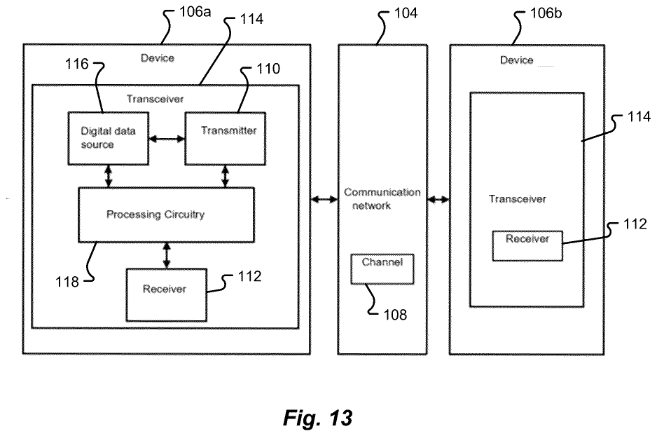

As shown in FIG. 13, in one specific but non-limiting example, the communication network 104 is a network that enables data transmission between the devices 106a and 106b using data signals (e.g., digital, optical, wireless signals).

Each type of network offers specific advantages tailored to different operational requirements. For instance, an IP network or Ethernet network may provide widespread compatibility and ease of integration, supporting various protocols and applications across the datacenter 102 and the network device(s) 106 (and/or external devices). An InfiniBand network may offer high throughput and low latency, ideal for HPC environments where rapid data transfer and minimal delay are required. Fibre Channel networks may be employed for their robust performance in storage area networks (SANs), ensuring fast and reliable access to storage resources. Cellular and wireless communication networks may be used to extend connectivity to remote or mobile devices for increased flexibility and accessibility.

As noted above, the network devices 106a, 106b may include one or more of Personal Computer (PC), a laptop, a tablet, a smartphone, a server, a collection of servers, and/or any suitable computing device for sending and receiving signals over the communication network 104. In at least one example embodiment, the one or more network devices 106 correspond to another datacenter, similar to or the same as datacenter 102.

Each network device 106 may be provided with transmitter functionality 110, receiver functionality 112, and/or transceiver functionality 114. The transmitter functionality 110, receiver functionality 112, and/or transceiver functionality 114 may include hardware and/or software to support the sending and/or receiving of data across the communication network 104, through one or more communication channels 108, for example.

A network device 106 may also include a digital data source 116 and/or processing circuitry 118 to support interactions within the transceiver 114 or to support interactions between components of the transceiver 114 and other components of the device 106. For instance, the processing circuitry 118 may be included in the transceiver 114 as illustrated or may be external to the transceiver 114, without departing from the scope of the present disclosure.

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

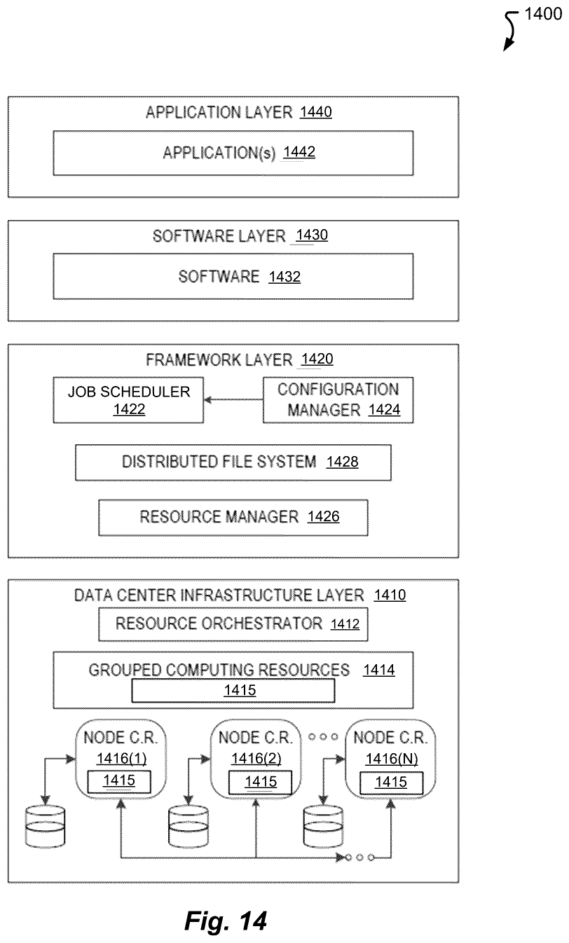

FIG. 14 illustrates additional components of an example datacenter 1400 according to at least some embodiments of the present disclosure. The datacenter 1400 may also include one or more modules subject to one or more cooling/thermal management features as described herein.

In at least one embodiment, datacenter 1400 includes a datacenter infrastructure layer 1410, a framework layer 1420, a software layer 1430, and an application layer 1440. In at least one embodiment, the infrastructure layer 1410, the framework layer 1420, the software layer 1430, and the application layer 1440 may be partly or fully provided via computing components on server trays located in racks of the datacenter 1400 (or of another datacenter, such as the datacenter 102). This enables cooling systems of the present disclosure to direct cooling to certain ones of the computing features and the interconnect features, in an efficient and effective manner. Further, aspects of the datacenter 1400, including the datacenter infrastructure layer 1410, the framework layer 1420, the software layer 1430, and the application layer 1440 may be used to support selection or design of the intermediate layers. As such, the discussion in reference to FIG. 14 may be understood to apply to the hardware and software features required to enable or support cooling functionality, for instance.

In at least one embodiment, as in FIG. 14, datacenter infrastructure layer 1410 may include a resource orchestrator 1412, grouped computing resources 1414, and node computing resources (“node C.R.s”) 1416(1)-1416(N), where “N” represents any whole, positive integer. In at least one embodiment, node C.R.s 1416(1)-1416(N) may include, but are not limited to, any number of central processing units (“CPUs”) or other processors (including accelerators, field programmable gate arrays (FPGAs), graphics processors, etc.), memory devices (such as dynamic read-only memory), storage devices (such as solid state or disk drives), network input/output (“NW I/O”) devices, network switches, virtual machines (“VMs”), power modules, and cooling modules, etc. In at least one embodiment, one or more node C.R.s from among node C.R.s 1416(1)-1416(N) may be a server having one or more of above-mentioned computing resources.

In at least one embodiment, grouped computing resources 1414 may include separate groupings of node C.R.s housed within one or more racks (not shown), or many racks housed in datacenters at various geographical locations (also not shown). Separate groupings of node C.R.s within grouped computing resources 1414 may include grouped compute, network, memory or storage resources that may be configured or allocated to support one or more workloads. In at least one embodiment, several node C.R.s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 1412 may configure or otherwise control one or more node C.R.s 1416(1)-1416(N) and/or grouped computing resources 1414. In at least one embodiment, resource orchestrator 1412 may include a software design infrastructure (“SDI”) management entity for datacenter 1400. In at least one embodiment, resource orchestrator may include hardware, software or some combination thereof.

In at least one embodiment, as shown in FIG. 14, framework layer 1420 includes a job scheduler 1422, a configuration manager 1424, a resource manager 1426 and a distributed file system 1428. In at least one embodiment, framework layer 1420 may include a framework to support software 1432 of software layer 1430 and/or one or more application(s) 1442 of application layer 1440. In at least one embodiment, software 1432 or application(s) 1442 may respectively include web-based service software or applications, such as those provided by Amazon Web Services, Google Cloud and Microsoft Azure. In at least one embodiment, framework layer 1420 may be, but is not limited to, a type of free and open-source software web application framework such as Apache Spar™ (hereinafter “Spark”) that may utilize distributed file system 1428 for large-scale data processing (such as “big data”). In at least one embodiment, job scheduler 1422 may include a Spark driver to facilitate scheduling of workloads supported by various layers of datacenter 1400. In at least one embodiment, configuration manager 1424 may be capable of configuring different layers such as software layer 1430 and framework layer 1420 including Spark and distributed file system 1428 for supporting large-scale data processing. In at least one embodiment, resource manager 1426 may be capable of managing clustered or grouped computing resources mapped to or allocated for support of distributed file system 1428 and job scheduler 1422. In at least one embodiment, clustered or grouped computing resources may include grouped computing resource 1414 at datacenter infrastructure layer 1410. In at least one embodiment, resource manager 1426 may coordinate with resource orchestrator 1412 to manage these mapped or allocated computing resources.

In at least one embodiment, software 1432 included in software layer 1430 may include software used by at least portions of node C.R.s 1416(1)-1416(N), grouped computing resources 1414, and/or distributed file system 1428 of framework layer 1420. One or more types of software may include, but are not limited to, Internet web page search software, e-mail virus scan software, database software, and streaming video content software.

In at least one embodiment, application(s) 1442 included in application layer 1440 may include one or more types of applications used by at least portions of node C.R.s 1416(1)-1416(N), grouped computing resources 1414, and/or distributed file system 1428 of framework layer 1420. One or more types of applications may include, but are not limited to, any number of a genomics application, a cognitive compute, and a machine learning application, including training or inferencing software, machine learning framework software (such as PyTorch, TensorFlow, Caffe, etc.) or other machine learning applications used in conjunction with one or more embodiments.

In at least one embodiment, any of configuration manager 1424, resource manager 1426, and resource orchestrator 1412 may implement any number and type of self-modifying actions based on any amount and type of data acquired in any technically feasible fashion. In at least one embodiment, self-modifying actions may relieve a datacenter operator of datacenter 1400 from making possibly bad configuration decisions and possibly avoiding underutilized and/or poor performing portions of a datacenter.

In at least one embodiment, datacenter 1400 may include tools, services, software or other resources to train one or more machine learning models or predict or infer information using one or more machine learning models according to one or more embodiments described herein. In at least one embodiment, a machine learning model may be trained by calculating weight parameters according to a neural network architecture using software and computing resources described above with respect to datacenter 1400. In at least one embodiment, trained machine learning models corresponding to one or more neural networks may be used to infer or predict information using resources described above with respect to datacenter 1400 by using weight parameters calculated through one or more training techniques. Deep learning may be advanced using any appropriate learning network and the computing capabilities of the datacenter 1400. As such, a deep neural network (DNN), a recurrent neural network (RNN) or a convolutional neural network (CNN) may be supported either simultaneously or concurrently using the hardware in the datacenter. Once a network is trained and successfully evaluated to recognize data within a subset or a slice, for instance, the trained network can provide similar representative data for using with the collected data.

In at least one embodiment, datacenter 1400 may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or perform inferencing of information, such as pressure, flow rates, temperature, and location information, or as any other artificial intelligence service.

Inference and/or training logic 1415 may be used to perform inferencing and/or training operations associated with one or more embodiments. In at least one embodiment, inference and/or training logic 1415 may be used in a datacenter 1400 (whether in grouped computing resources 1414, in one or more node C.R.s 1416(1)-1416(N), or elsewhere) or in other systems described herein, for inferencing or predicting operations based, at least in part, on weight parameters calculated using neural network training operations, neural network functions and/or architectures, or neural network use cases described herein. In at least one embodiment, inference and/or training logic 1415 may include, without limitation, hardware logic in which computational resources are dedicated or otherwise exclusively used in conjunction with weight values or other information corresponding to one or more layers of neurons within a neural network. In at least one embodiment, inference and/or training logic 1415 may be used in conjunction with an application-specific integrated circuit (ASIC), such as a Tensorflow® Processing Unit from Google, an inference processing unit (IPU) from Graphcore™, or a Nervana® (such as “Lake Crest”) processor from Intel Corp.

In at least one embodiment, inference and/or training logic 1415 may be used in conjunction with central processing unit (CPU) hardware, graphics processing unit (GPU) hardware or other hardware, such as field programmable gate arrays (FPGAs). In at least one embodiment, inference and/or training logic 1415 includes, without limitation, code and/or data storage modules which may be used to store code (such as graph code), weight values and/or other information, including bias values, gradient information, momentum values, and/or other parameter or hyperparameter information. In at least one embodiment, each of the code and/or data storage modules is associated with a dedicated computational resource. In at least one embodiment, the dedicated computational resource includes computational hardware that further include one or more ALUs that perform mathematical functions, such as linear algebraic functions, only on information stored in code and/or data storage modules, and results from which are stored in an activation storage module of the inference and/or training logic 1415.

The switches within each layer (e.g., edge layer, aggregation layer, core layer) may be 1 U switches. The switches may be electrical switches, optical switches, hybrid electro-optical switches, or any combination thereof. The switches may be implemented with suitable hardware and/or software that enables the routing of signals in the appropriate domain. For example, an electrical switch may include receivers that receive and convert optical signals into electrical signals for routing within the electrical switch. A receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In some embodiments, receiver/transmitter pairs may be integrated into a single transceiver. Each electrical switch may also include internal switching circuitry for routing electrical signals within the electrical switch.

A switch, whether electric, optoelectronic, and/or quantum, may include input circuit(s) and output circuit(s), linked by switching core. In some embodiments, a switch may include multiple inputs and outputs.

A number of architectures of this type have been proposed, including “Next Generation I/O” (NGIO) and “Future I/O” (FIO), culminating in the “InfiniBand” architecture, which has been advanced by a consortium led by a group of industry leaders (including Intel, Sun, Hewlett Packard, IBM, Compaq, Dell and Microsoft). Storage Area Networks (SAN) provide a similar, packetized, serial approach to high-speed storage access, which can also be implemented using an InfiniBand fabric.

Communications between a parallel bus and a packet network generally require a communications interface, to convert bus cycles into appropriate packets and vice versa. For example, a host channel adapter or target channel adapter can be used to link a parallel bus, such as the PCI bus, to the InfiniBand fabric. When the adapter receives data from a device on the PCI bus, it inserts the data in the payload of an InfiniBand packet, and then adds an appropriate header and error checking code, such as a cyclic redundancy check (CRC) code, as required for network transmission. The InfiniBand packet header includes a routing header and a transport header. The routing header contains information at the data link protocol level, including fields required for routing the packet within and between fabric subnets. The transport header contains higher-level, end-to-end transport protocol information. Similar headers are used in other types of packet networks known in the art, such as Internet Protocol (IP) networks.

Embodiments of the present disclosure may comprise any suitable material known in the art (e.g., carbon steel, aluminum, polymers, ceramics, and the like), particularly materials possessing high thermal conductivity. By way of example, cage receptacle assemblies as described herein may be created by an extrusion and/or machine process. In such an example, a single body of fixed cross-sectional area may be produced by an extrusion process. This single body may be created via pushing a base material (e.g., a polymer) through a dimensioned die such that the cage body 601 of the cage receptacle assembly is created. In some embodiments, the single body may be created as two separate elements (e.g., a top cage member and bottom cage member) where the two separate elements are further attached to form the single body. This extruded body may then be modified through a machine process whereby material is removed from the extruded body to create the finished cage receptacle assembly 600. The machining process may include any or all of micro machining, turning, milling, drilling, grinding, water jet cutting, EDM, AFM, USM, CNC, and the like, in any order or combination. Although described as an extrusion and machine process of a single piece of material, any portion or sub-portion of the cage receptacle assembly may be separately formed or attached without departing from the scope of this disclosure.

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components (e.g., components of printed circuit boards, transceivers, cables, etc.) may be used in conjunction with the cage receptacle assembly. Therefore, it is to be understood that the disclosures are not to be limited to the specific embodiments disclosed and that modifications and other embodiments are intended to be included within the scope of the appended claims.

It is to be appreciated that any feature described herein can be claimed in combination with any other feature(s) as described herein, regardless of whether the features come from the same described embodiment.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A system, comprising:
a processing and/or memory layer comprising at least one of a processing unit and a memory die; and
a cooling substrate that cools a bottom side of the processing and/or memory layer.

2. The system of claim 1, further comprising a semiconductor interposer.

3. The system of claim 2, wherein the processing unit is positioned between the memory die and the semiconductor interposer.

4. The system of claim 2, wherein the semiconductor interposer comprises co-packaged optics mounted thereon.

5. The system of claim 1, further comprising a cold plate that cools a top side of the processing and/or memory layer.

6. The system of claim 5, wherein the processing unit is positioned between the memory die and the cold plate.

7. The system of claim 1, wherein the cooling substrate comprises one or more microfluidic channels therein that carry a fluid to facilitate heat transfer away from the processing and/or memory layer.

8. The system of claim 1, wherein the cooling substrate comprises a thermally-conductive material suitable to conduct heat away from the processing and/or memory layer.

9. The system of claim 1, wherein the processing unit comprises a Graphics Processing Unit (GPU).

10. The system of claim 1, wherein the memory die comprises a high-bandwidth memory (HBM) stack and/or a dynamic random access memory (DRAM) layer.

11. The system of claim 1, wherein the processing and/or memory layer comprises both the processing unit and the memory die.

12. The system of claim 11, wherein the processing unit is positioned between the memory die and the cooling substrate.

13. The system of claim 11, wherein the memory die is positioned between the processing unit and the cooling substrate.

14. The system of claim 11, wherein the processing and/or memory layer comprises a 2.5D package.

15. The system of claim 11, wherein the processing and/or memory layer comprises a 3D package.

16. The system of claim 1, wherein the cooling substrate comprises one or more conductive vias.

17. The system of claim 16, wherein the cooling substrate comprises one or more microfluidic channels therein that carry a fluid to facilitate heat transfer away from the processing and/or memory layer, wherein the one or more conductive vias are electrically isolated from the one or more microfluidic channels.

18. A bottom-cooled processing stack, comprising:
a cooling substrate comprising one or more microfluidic channels therein; and
at least one processing unit positioned relative to the cooling substrate such that a bottom side of the at least one processing unit is cooled by a fluid flowing through the one or more microfluidic channels.

19. The bottom-cooled processing stack of claim 18, further comprising at least one memory die.

20. The bottom-cooled processing stack of claim 19, wherein the at least one memory die is positioned between the at least one processing unit and the cooling substrate.

21. The bottom-cooled processing stack of claim 19, wherein the at least one processing unit is positioned between the at least one memory die and the cooling substrate.

22. The bottom-cooled processing stack of claim 19, further comprising a semiconductor interposer.

23. The bottom-cooled processing stack of claim 19, further comprising a cold plate that cools a top side of the at least one processing unit and the at least one memory die.

24. The bottom-cooled processing stack of claim 23, wherein the at least one processing unit and the at least one memory die are provided in a 2.5D or 3D package that is sandwiched between the cold plate and the cooling substrate.

25. The bottom-cooled processing stack of claim 18, wherein the cooling substrate comprises one or more microfluidic channels and one or more conductive vias that are electrically isolated from the one or more microfluidic channels.

26. A bottom-cooled processing stack, comprising:
a cooling substrate comprising one or more heat transfer channels therein; and
at least one processing unit positioned relative to the cooling substrate such that a bottom side of the at least one processing unit is cooled by the one or more heat transfer channels of the cooling substrate.
